(19) United States
(12) Patent Application Publication
(10) Pub. No.: US 2023/0321953 A1
(43) Pub. Date: Oct. 12, 2023

(54) LIQUID CRYSTAL POLYMER FILM, METHOD FOR MANUFACTURING SAME, AND LAMINATE

(71) Applicant: FUJIFILM Corporation, Tokyo (JP)

(72) Inventor: Yasuyuki SASADA, Shizuoka (JP)

(73) Assignee: FUJIFILM Corporation, Tokyo (JP)

(21) Appl. No.: 18/319,473

(22) Filed: May 17, 2023

Related U.S. Application Data
(63) Continuation of application No. PCT/JP2021/043507, filed on Nov. 26, 2021.

(30) Foreign Application Priority Data
Nov. 27, 2020 (JP) 2020-197563

(51) Int. Cl. B32B 15/08; B32B 15/20

(52) U.S. Cl. CPC B32B 15/08; B32B 15/20; B32B 2250/02; B32B 2305/55; B32B 2307/7376

(57) ABSTRACT

Provided are a liquid crystal polymer film containing a liquid crystal polymer, in which the liquid crystal polymer film includes a portion where a density of the liquid crystal polymer is low and a portion where the density of the liquid crystal polymer is high; a liquid crystal polymer film containing a liquid crystal polymer and a compound incompatible with the liquid crystal polymer; a liquid crystal polymer film containing a liquid crystal polymer and a compound A, in which an absolute value of a difference between an SP value of the liquid crystal polymer, which is determined by Hoy method, and an SP value of the compound A, which is determined by Hoy method, is 0.1 MPa^{0.5} or more; and a method for manufacturing these polymer films; and a laminate using the liquid crystal polymer film.

### CROSS-REFERENCE TO RELATED APPLICATIONS

This application is a continuation application of International Application No. PCT/JP2021/043507, filed Nov. 26, 2021, the disclosure of which is incorporated herein by reference in its entirety. Further, this application claims priority from Japanese Patent Application No. 2020-197563, filed Nov. 27, 2020, the disclosure of which is incorporated herein by reference in its entirety.

### BACKGROUND OF THE INVENTION

### 1. Field of the Invention

The present disclosure relates to a liquid crystal polymer film, a method for manufacturing the same, and a laminate.

### 2. Description of the Related Art

In recent years, frequencies used in a communication equipment tend to be extremely high. In order to suppress transmission loss in a high frequency band, insulating materials used in a circuit board are required to have a lowered relative permittivity and a lowered dielectric loss tangent.

In the related art, polyimide is commonly used as the insulating material used in the circuit board, a liquid crystal polymer which has high heat resistance and low water absorption and is small in loss in the high frequency band has been attracted.

As a polymer film in the related art, for example, JP2020-26474A discloses a liquid crystalline polyester film that contains at least liquid crystalline polyester, in which, in a case where a first alignment degree is set to an alignment degree with respect to a first direction parallel to a main surface of the liquid crystalline polyester film, and a second alignment degree is set to an alignment degree with respect to a second direction parallel to the main surface and perpendicular to the first direction, a first alignment degree/second alignment degree that is a ratio of the first alignment degree and the second alignment degree is equal to or greater than 0.95 and equal to or less than 1.04, and a third alignment degree of the liquid crystalline polyester that is measured by a wide angle X-ray scattering method in a direction parallel to the main surface is equal to or greater than 60.0%.

In addition, as a microporous film in the related art, a film disclosed in JP1988-141607A (JP-S63-141607A) is known.

JP1988-141607A (JP-S63-141607A) discloses a microporous film including a minimum pore diameter layer inside the film, which has a pore diameter distribution in a film thickness direction, in which the maximum pore diameter of the microporous film, which is measured by the method of ASTM-316-80, is 1.8 times or less an average pore diameter.

### SUMMARY OF THE INVENTION

An object to be achieved by an aspect of the present invention is to provide a liquid crystal polymer film having a low volatile component content, and a method for manufacturing the liquid crystal polymer film.

An object to be achieved by another aspect of the present invention is to provide a laminate using the above-described liquid crystal polymer film.

The methods for achieving the above-described objects include the following aspects.

<1> A liquid crystal polymer film comprising:
a liquid crystal polymer,
in which the liquid crystal polymer film includes a portion where a density of the liquid crystal polymer is low and a portion where the density of the liquid crystal polymer is high.

<2> The liquid crystal polymer film according to <1>,
in which the portion where the density of the liquid crystal polymer is low includes a void.

<3> The liquid crystal polymer film according to <1> or <2>,
in which the portion where the density of the liquid crystal polymer is low and the portion where the density of the liquid crystal polymer is high have an interpenetrating network structure, a cylinder structure, a lamella structure, or a sea-island structure.

<4> A liquid crystal polymer film comprising:
a liquid crystal polymer; and
a compound incompatible with the liquid crystal polymer.

<5> A liquid crystal polymer film comprising:
a liquid crystal polymer; and
a compound A,
in which an absolute value of a difference between an SP value of the liquid crystal polymer, which is determined by Hoy method, and an SP value of the compound A, which is determined by Hoy method, is 0.1 MPa^{0.5} or more.

<6> The liquid crystal polymer film according to any one of <1> to <5>,
in which the liquid crystal polymer film includes a layer A and a layer B on at least one surface of the layer A.

<7> The liquid crystal polymer film according to <6>,
in which the liquid crystal polymer film further includes a layer C, and
the layer B, the layer A, and the layer C are provided in this order.

<8> The liquid crystal polymer film according to any one of <1> to <7>,
in which a linear expansion coefficient of the liquid crystal polymer film is −20 ppm/K to 50 ppm/K.

<9> The liquid crystal polymer film according to any one of <1> to <8>,
in which a dielectric loss tangent of the liquid crystal polymer film is 0.01 or less.

<10> The liquid crystal polymer film according to any one of <1> to <9>, further comprising:
a filler.

<11> The liquid crystal polymer film according to <10>,
in which a number density of the filler is higher inside the liquid crystal polymer film than on a surface of the liquid crystal polymer film.

<12> The liquid crystal polymer film according to any one of <1> to <11>,
in which the liquid crystal polymer has a constitutional unit represented by any of Formulae (1) to (3),

—O—Ar¹—CO— Formula (1)

—CO—Ar²—CO— Formula (2)

—X—Ar³—Y— Formula (3)
in Formulae (1) to (3), Ar′ represents a phenylene group, a naphthylene group, or a biphenylylene group, Ar² and Ar³ each independently represent a phenylene group, a naphthylene group, a biphenylylene group, or a group represented by Formula (4), X and Y each independently represent an oxygen atom or an imino group, and hydrogen atoms in Ar¹ to Ar³ may be each independently substituted with a halogen atom, an alkyl group, or an aryl group,

—Ar⁴—Z—Ar⁵— Formula (4)
in Formula (4), Ar⁴ and Ary each independently represent a phenylene group or a naphthylene group, and Z represents an oxygen atom, a sulfur atom, a carbonyl group, a sulfonyl group, or an alkylene group.

<13> A laminate comprising:
the liquid crystal polymer film according to any one of <1> to <12>; and
a metal layer disposed on at least one surface of the liquid crystal polymer film.

<14> A laminate comprising:
the liquid crystal polymer film according to <6>; and
a metal layer disposed on a surface of the layer B side.

<15> The laminate according to <14>,
in which a thickness of the layer B is larger than a thickness of the metal layer.

<16> The laminate according to <14> or <15>,
in which the metal layer is a copper layer, and
a peel strength between the layer B and the copper layer is 0.5 kN/m or more.

<17> A laminate comprising:
the liquid crystal polymer film according to <7>; and
a metal layer disposed on a surface of the layer C side.

<18> The laminate according to <17>,
in which the metal layer is a copper layer, and
a peel strength between the layer C and the copper layer is 0.5 kN/m or more.

<19> A method for manufacturing the liquid crystal polymer film according to any one of <1> to <12>, the method comprising, in the following order:
a casting step of extruding a composition containing the liquid crystal polymer and a solvent A onto a support to produce a casting film;
a liquid immersion step of immersing the casting film in a solvent B having a boiling point lower than a melting point of the liquid crystal polymer; and
a drying step of removing at least a part of the solvent B contained in the casting film.

According to the aspect of the present invention, it is possible to provide a liquid crystal polymer film having a low volatile component content, and a method for manufacturing the liquid crystal polymer film.

Further, according to another aspect of the present invention, it is possible to provide a laminate using the above-described liquid crystal polymer film.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

Further, in the present specification, a numerical range shown using “to” indicates a range including numerical values described before and after “to” as a lower limit and an upper limit.

In a numerical range described in a stepwise manner in the present disclosure, an upper limit or a lower limit described in one numerical range may be replaced with an upper limit or a lower limit in another numerical range described in a stepwise manner. Further, in a numerical range described in the present disclosure, an upper limit or a lower limit described in the numerical range may be replaced with a value described in an example.

Further, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, the concept of “(meth)acryl” includes both acryl and methacryl, and the concept of “(meth)acryloyl” includes both acryloyl and methacryloyl.

Further, the term “step” in the present specification indicates not only an independent step but also a step which cannot be clearly distinguished from other steps as long as the intended purpose of the step is achieved.

Further, in the present disclosure, “% by mass” has the same definition as that for “% by weight”, and “part by mass” has the same definition as that for “part by weight”.

Furthermore, in the present disclosure, a combination of two or more preferred embodiments is a more preferred embodiment.

Further, the weight-average molecular weight (Mw) and the number-average molecular weight (Mn) in the present disclosure are molecular weights converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

(Liquid Crystal Polymer Film)

A first embodiment of the liquid crystal polymer film according to the present disclosure contains a liquid crystal polymer, in which the liquid crystal polymer film includes a portion where a density of the liquid crystal polymer is low and a portion where the density of the liquid crystal polymer is high.

A second embodiment of the liquid crystal polymer film according to the present disclosure contains a liquid crystal polymer and a compound incompatible with the liquid crystal polymer.

A third embodiment of the liquid crystal polymer film according to the present disclosure contains a liquid crystal polymer and a compound A, in which an absolute value of a difference between an SP value of the liquid crystal polymer, which is determined by Hoy method, and an SP value of the compound A, which is determined by Hoy method, is 0.1 MPa^{0.5} or more.

In the present specification, the expression “liquid crystal polymer film according to the embodiment of the present disclosure” denotes all the first embodiment, the second embodiment, and the third embodiment described above, unless otherwise specified.

The present inventor has found that the liquid crystal polymer film in the related art has a problem that the volatile component content is large.

As a result of intensive research conducted by the present inventor, it has been found that, with the above-described configuration, it is possible to provide a liquid crystal polymer film having a low volatile component content.

The detailed mechanism for obtaining the above-described effects is not clear, but assumed as follows.

In a case of including a portion where a density of the liquid crystal polymer is low and a portion where the density of the liquid crystal polymer is high, in a case of containing a compound incompatible with the liquid crystal polymer, or in a case where a compound A is contained and an absolute value of a difference between an SP value of the liquid crystal polymer, which is determined by Hoy method, and an SP value of the compound A, which is determined by Hoy method, is 0.1 MPa^{0.5} or more, by forming concentration fluctuations of the liquid crystal polymer in the liquid crystal polymer film and forming a portion having a density different from that of the liquid crystal polymer, it is presumed that a path through which the volatile component such as a solvent and a low-molecular-weight component of the liquid crystal polymer can easily diffuse and be released can be formed during film formation, and a liquid crystal polymer film with a low volatile component content is obtained.

The volatile component in the present disclosure is a component which volatilizes in a case where the liquid crystal polymer film is heated at 300° C. for 1 hour.

In the first embodiment of the liquid crystal polymer film according to the present disclosure, the liquid crystal polymer film includes a portion where a density of the liquid crystal polymer is low and a portion where the density of the liquid crystal polymer is high.

It is sufficient that the above-described portion where the density of the liquid crystal polymer is low and the above-described portion where the density of the liquid crystal polymer is high are at least two kinds of portions where there is a difference in content of the liquid crystal polymer.

Examples thereof include a case where a content of the liquid crystal polymer in the above-described portion where the density of the liquid crystal polymer is low is 50% by mass and a content of the liquid crystal polymer in the above-described portion where the density of the liquid crystal polymer is high is 90% by mass, and
a case where a content of the liquid crystal polymer in the above-described portion where the density of the liquid crystal polymer is low is 0% by mass, like voids, and a content of the liquid crystal polymer in the above-described portion where the density of the liquid crystal polymer is high is 100% by mass.

In the second embodiment or the third embodiment of the liquid crystal polymer film according to the present disclosure, from the viewpoint of low dielectric loss tangent and reduction of volatile components, it is preferable to include the above-described portion where the density of the liquid crystal polymer is low and the above-described portion where the density of the liquid crystal polymer is high.

In the liquid crystal polymer film according to the embodiment of the present disclosure, a ratio (volume ratio or mass ratio) of the above-described portion where the density of the liquid crystal polymer is low and the above-described portion where the density of the liquid crystal polymer is high is not particularly limited, but from the viewpoint of low dielectric loss tangent and reduction of volatile components, the volume ratio thereof is preferably the above-described portion where the density of the liquid crystal polymer is low:the above-described portion where the density of the liquid crystal polymer is high=5:95 to 95:5, more preferably the above-described portion where the density of the liquid crystal polymer is low:the above-described portion where the density of the liquid crystal polymer is high=10:90 to 90:10, still more preferably the above-described portion where the density of the liquid crystal polymer is low:the above-described portion where the density of the liquid crystal polymer is high=20:80 to 80:20, and particularly preferably the above-described portion where the density of the liquid crystal polymer is low:the above-described portion where the density of the liquid crystal polymer is high=30:70 to 70:30.

In addition, in the liquid crystal polymer film according to the embodiment of the present disclosure, from the viewpoint of low dielectric loss tangent and reduction of volatile components, it is preferable that the above-described portion where the density of the liquid crystal polymer is low and the above-described portion where the density of the liquid crystal polymer is high have an interpenetrating network structure, a cylinder structure, a lamella structure, or a sea-island structure, and from the viewpoint of reduction of volatile components, it is more preferable to have an interpenetrating network structure, a cylinder structure, or a lamella structure, and it is still more preferable to have an interpenetrating network structure.

Furthermore, in the liquid crystal polymer film according to the embodiment of the present disclosure, from the viewpoint of low dielectric loss tangent and reduction of volatile components, it is preferable that the above-described portion where the density of the liquid crystal polymer is low includes a void.

With regard to the above-described portion where the density of the liquid crystal polymer is low and the above-described portion where the density of the liquid crystal polymer is high, the liquid crystal polymer film according to the embodiment of the present disclosure also includes a case where the liquid crystal polymer film has a multilayer structure, and it is preferable that one layer includes both of the above-described portion where the density of the liquid crystal polymer is low and the above-described portion where the density of the liquid crystal polymer is high.

In addition, in the liquid crystal polymer film according to the embodiment of the present disclosure, it is preferable that the above-described portion where the density of the liquid crystal polymer is low and the above-described portion where the density of the liquid crystal polymer is high each independently has a portion having a volume of 1,000 nm³ or more, and it is more preferable to each independently have a portion having a volume of 0.001 μm³ or more. The upper limit value thereof is preferably 99% by volume or less of the total volume of the liquid crystal polymer film.

In the liquid crystal polymer film according to the embodiment of the present disclosure, a method for forming the above-described portion where the density of the liquid crystal polymer is low and the above-described portion where the density of the liquid crystal polymer is high is not particularly limited, and examples thereof include a method of forming a layer by mixing the liquid crystal polymer and a compound incompatible with the liquid crystal polymer (including those corresponding to the compound A), a method of forming a layer using a void-forming agent as described later, and a method of forming a layer using a foaming agent.

As a method for confirming the above-described portion where the density of the liquid crystal polymer is low and the above-described portion where the density of the liquid crystal polymer is high in the liquid crystal polymer film according to the embodiment of the present disclosure, a method of observing a surface of the liquid crystal polymer film or observing a cross section of the liquid crystal polymer film, and a method of combining content analysis of the liquid crystal polymer, content analysis of components other than the liquid crystal polymer, and the like may be used. In addition, the surface or the cross section may be dyed as necessary. Alternatively, as another method, a viscoelastic distribution in the surface of the liquid crystal polymer film or the cross section of the liquid crystal polymer film may be confirmed using a scanning probe microscope (for example, observing in VE-AFM mode using SPA400 manufactured by Hitachi High-Tech Science Corporation).

In a case where a metal layer is laminated on the liquid crystal polymer film, the metal layer is etched and the measurement is performed using the liquid crystal polymer film taken out.

<Compound Incompatible with Liquid Crystal Polymer and Compound A>

The second embodiment of the liquid crystal polymer film according to the present disclosure contains a compound incompatible with the liquid crystal polymer.

In the first embodiment or the third embodiment of the liquid crystal polymer film according to the present disclosure, from the viewpoint of low dielectric loss tangent and reduction of volatile components, it is preferable to contain the compound incompatible with the liquid crystal polymer.

In the liquid crystal polymer film according to the embodiment of the present disclosure, the above-described compound incompatible with the liquid crystal polymer is not particularly limited as long as it is not compatible with the liquid crystal polymer coexisting in the liquid crystal polymer film, and the above-described compound incompatible with the liquid crystal polymer may be a low-molecular-weight compound having a molecular weight of less than 1,000 or a high-molecular-weight compound having a weight-average molecular weight Mw of 1,000 or more. For example, the above-described compound incompatible with the liquid crystal polymer may be a liquid crystal polymer B which is different from the liquid crystal polymer, or the compound A in which the absolute value of the difference in SP value with the liquid crystal polymer, which is determined by Hoy method, is 0.1 MPa^{0.5} or more.

In the liquid crystal polymer film according to the embodiment of the present disclosure, the above-described compound incompatible with the liquid crystal polymer is preferably the compound A.

In the present disclosure, the fact that the liquid crystal polymer and the compound A are “incompatible” is confirmed by the following method.

First, the liquid crystal polymer and the compound A to be used in combination are each measured by a differential scanning calorimetry (DSC) measurement to select characteristic inflection points and peaks, such as a glass transition temperature (Tg) and a melting point (Tm).

A film containing the liquid crystal polymer and the compound A to be used in combination is measured by the DSC, and a case where the selected inflection point or peak appears to be divided is determined as “incompatible” and a case where the selected inflection point or peak appears to be single is determined as “compatible”. The inflection point and the peak temperature may be slightly raised or lowered.

In a case where it is difficult to determine by the DSC, using an imaging image of time-of-flight secondary ion mass spectrometry (TOF-SIMS), it can also be determined whether or not a fragment derived from the liquid crystal polymer and a fragment derived from the compound A to be used in combination are spatially separated.

The third embodiment of the liquid crystal polymer film according to the present disclosure contains a compound A, in which an absolute value of a difference between an SP value of the liquid crystal polymer, which is determined by Hoy method, and an SP value of the compound A, which is determined by Hoy method, is 0.1 MPa^{0.5} or more.

From the viewpoint of low dielectric loss tangent and reduction of volatile components, it is preferable that the first embodiment or the second embodiment of the liquid crystal polymer film according to the present disclosure contains the compound A, in which the absolute value of the difference between the SP value of the liquid crystal polymer, which is determined by Hoy method, and the SP value of the compound A, which is determined by Hoy method, is 0.1 MPa^{0.5} or more.

In addition, in the second embodiment of the liquid crystal polymer film according to the present disclosure, from the viewpoint of low dielectric loss tangent and reduction of volatile components, it is preferable that the above-described compound incompatible with the liquid crystal polymer includes the compound A, and it is more preferable that the above-described compound incompatible with the liquid crystal polymer is the compound A.

In the third embodiment of the liquid crystal polymer film according to the present disclosure, the absolute value of the difference between the SP value of the liquid crystal polymer, which is determined by Hoy method, and the SP value of the compound A, which is determined by Hoy method, is 0.1 MPa^{0.5} or more, and from the viewpoint of incompatibility, low dielectric loss tangent, and reduction of volatile components, the absolute value thereof is preferably 1 MPa^{0.5} or more, more preferably 3 MPa^{0.5} or more, and particularly preferably 5 MPa^{0.5} or more and 50 MPa^{0.5} or less.

In the first embodiment or the second embodiment of the liquid crystal polymer film according to the present disclosure, from the viewpoint of incompatibility, low dielectric loss tangent, and reduction of volatile components, the absolute value of the difference between the SP value of the liquid crystal polymer, which is determined by Hoy method, and the SP value of the compound A, which is determined by Hoy method, is preferably 0.1 MPa^{0.5} or more, more preferably 1 MPa^{0.5} or more, still more preferably 3 MPa^{0.5} or more, and particularly preferably 5 MPa^{0.5} or more and 50 MPa^{0.5} or less.

In the present disclosure, the solubility parameter value (SP value) determined by Hoy method is calculated from the molecular structure of the compound by the method described in Polymer Handbook fourth edition. In addition, for example, in a case where the liquid crystal polymer is a mixture of a plurality of kinds of liquid crystal polymers, an SP value is obtained by calculating an SP value of each constitutional unit and calculating the weighted average value thereof. Even in a case where the compound A is a mixture of a plurality of kinds of compounds A, the SP value is obtained by the same method.

Hereinafter, the compound A will be described, and unless otherwise specified, preferred aspects of the compound A are the same as preferred aspects of the compound incompatible with the liquid crystal polymer.

The compound A may be a low-molecular-weight compound having a molecular weight of less than 1,000 or a high-molecular-weight compound having a weight-average molecular weight Mw of 1,000 or more.

In addition, the compound A may be a solid, a liquid, or a so-called void gas (preferably, air) at 25° C.

Specifically, preferred examples of the compound A include the liquid crystal polymer B different from the liquid crystal polymer, a fluorine-based polymer, a polymerized substance of a compound which has a cyclic aliphatic hydrocarbon group and a group having an ethylenically unsaturated bond, an aromatic polyether ketone, a polyphenylene ether, an aromatic vinyl resin, a polyimide resin, a water-soluble resin, and air.

Among these, as the compound A, from the viewpoint of low dielectric loss tangent and reduction of volatile components, an organic compound or a gas is preferable, and a resin (polymer compound) or a gas is more preferable.

From the viewpoint of low dielectric loss tangent, the compound A is preferably a compound having a dielectric loss tangent of 0.01 or less.

In addition, as the resin used as the compound A, from the viewpoint of strength, a resin having a weight-average molecular weight of 1,000 or more is preferable, a resin having a weight-average molecular weight of 2,000 or more is more preferable, a resin having a weight-average molecular weight of 3,000 or more is still more preferable, and a resin having a weight-average molecular weight of 5,000 or more and 200,000 or less is particularly preferable. In addition, in a case where the compound A is a liquid crystal polymer (that is, the above-described liquid crystal polymer B), a weight-average molecular weight thereof is preferably 13,000 or less.

From the viewpoint of low dielectric loss tangent and reduction of volatile components, it is preferable that the liquid crystal polymer B different from the liquid crystal polymer is a liquid crystal polymer incompatible with the liquid crystal polymer.

Preferred aspects of the liquid crystal polymer B different from the above-described liquid crystal polymer are the same as preferred aspects of the liquid crystal polymer (liquid crystal polymer A) described later, except that the absolute value of the difference between the SP value of the liquid crystal polymer, which is determined by Hoy method, and the SP value of the liquid crystal polymer B different from the liquid crystal polymer, which is determined by Hoy method, is 0.1 MPa^{0.5} or more.

From the viewpoint of heat resistance and mechanical strength, the compound A is preferably a fluorine-based polymer.

In the present disclosure, the type of the fluorine-based polymer used as the compound A is not particularly limited, and a known fluorine-based polymer can be used. However, a polymer having a dielectric loss tangent of 0.005 or less is preferable.

Examples of the fluorine-based polymer include polytetrafluoroethylene, polychlorotrifluoroethylene, polyvinylidene fluoride, polyvinyl fluoride, a perfluoroalkoxy fluororesin, an ethylene tetrafluoride/propylene hexafluoride copolymer, an ethylene/ethylene tetrafluoride copolymer, and an ethylene/chlorotrifluoroethylene copolymer.

Among these, preferred examples of the fluorine-based polymer include polytetrafluoroethylene.

In addition, examples of the fluorine-based polymer include a fluorinated α-olefin monomer, that is, an α-olefin monomer containing at least one fluorine atom; and a homopolymer and a copolymer optionally containing a constitutional unit derived from a non-fluorinated ethylenically unsaturated monomer reactive to the fluorinated α-olefin monomer.

Examples of the fluorinated α-olefin monomer include CF₂═CF₂, CHF═CF₂, CH₂═CF₂, CHCl═CHF, CClF═CF₂, CCl₂═CF₂, CClF═CClF, CHF═CCl₂, CH₂═CClF, CCl₂═CClF, CF₃CF═CF₂, CF₃CF═CHF, CF₃CH═CF₂, CF₃CH═CH₂, CHF₂CH═CHF, CF₃CF═CF₂, and perfluoro(alkyl having 2 to 8 carbon atoms) vinyl ether (for example, perfluoromethyl vinyl ether, perfluoropropyl vinyl ether, and perfluorooctyl vinyl ether). Among these, at least one monomer selected from the group consisting of tetrafluoroethylene (CF₂═CF₂), chlorotrifluoroethylene (CClF═CF₂), (perfluorobutyl)ethylene, vinylidene fluoride (CH₂═CF₂), and hexafluoropropylene (CF₂═CFCF₃) is preferable.

Examples of the non-fluorinated monoethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluorine-based polymer include polychlorotrifluoroethylene (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene) (PTFE), poly(tetrafluoroethylene-ethylene-propylene), poly(tetrafluoroethylene-hexafluoropropylene) (FEP), poly(tetrafluoroethylene-propylene) (FEPM), poly(tetrafluoroethylene-perfluoropropylene vinyl ether), poly(tetrafluoroethylene-perfluoroalkyl vinyl ether) (PFA) (for example, poly(tetrafluoroethylene-perfluoropropyl vinyl ether)), polyvinyl fluoride (PVF), polyvinylidene fluoride (PVDF), poly(vinylidene fluoride-chlorotrifluoroethylene), perfluoropolyether, perfluorosulfonic acid, and perfluoropolyoxetane.

The fluorine-based polymer may be used alone or in combination of two or more thereof.

The fluorine-based polymer is preferably at least one of FEP, PFA, ETFE, or PTFE. The FEP is available from Du Pont as the trade name of TEFLON (registered trademark) FEP or from DAIKIN INDUSTRIES, LTD. as the trade name of NEOFLON FEP; and the PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluorine-based polymer preferably includes PTFE. The PTFE can be included as a PTFE homopolymer, a partially modified PTFE homopolymer, or a combination including one or both of these. The partially modified PTFE homopolymer preferably contains a constitutional unit derived from a comonomer other than tetrafluoroethylene in an amount of less than 1% by mass based on the total mass of the polymer.

The fluorine-based polymer may be a crosslinkable fluoropolymer having a crosslinkable group. The crosslinkable fluoropolymer can be crosslinked by a known crosslinking method in the related art. One of the representative crosslinkable fluoropolymers is a fluoropolymer having a (meth)acryloxy group. For example, the crosslinkable fluoropolymer can be represented by Formula:

H₂C═CR′COO—(CH₂)ₙ—R—(CH₂)ₙ—OOCR′═CH₂
in the formula, R is a fluorine-based oligomer chain having two or more constitutional units derived from the fluorinated α-olefin monomer or the non-fluorinated monoethylenically unsaturated monomer, R′ is H or —CH₃, and n is 1 to 4. R may be a fluorine-based oligomer chain having a constitutional unit derived from tetrafluoroethylene.

In order to initiate a radical crosslinking reaction through the (meth)acryloxy group in the fluorine-based polymer, by exposing the fluoropolymer having a (meth)acryloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

The compound A is preferably a polymerized substance of a compound which has a cyclic aliphatic hydrocarbon group and a group having an ethylenically unsaturated bond.

Examples of the polymerized substance of a compound which has a cyclic aliphatic hydrocarbon group and a group having an ethylenically unsaturated bond include thermoplastic resins having a constitutional unit formed from a monomer having a cyclic olefin such as norbornene and a polycyclic norbornene-based monomer.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

It is sufficient that the polymerized substance of a compound which has a cyclic aliphatic hydrocarbon group and a group having an ethylenically unsaturated bond is a polymer obtained by polymerizing at least one compound which has a cyclic aliphatic hydrocarbon group and a group having an ethylenically unsaturated bond, and it may be a polymerized substance of two or more kinds of the compound which has a cyclic aliphatic hydrocarbon group and a group having an ethylenically unsaturated bond or a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

The compound A is preferably a polyphenylene ether.

In a case where heat curing is performed after film formation, from the viewpoint of heat resistance and film-forming property, a weight-average molecular weight (Mw) of the polyphenylene ether is preferably 500 to 5,000 and preferably 500 to 3,000. In addition, in a case where the heat curing is not performed, the weight-average molecular weight (Mw) of the polyphenylene ether is not particularly limited, but is preferably 3,000 to 100,000 and preferably 5,000 to 50,000.

In the polyphenylene ether, from the viewpoint of dielectric loss tangent and heat resistance, the average number of molecular terminal phenolic hydroxyl groups per molecule (the number of terminal hydroxyl groups) is preferably 1 to 5 and more preferably 1.5 to 3.

The number of hydroxyl groups or the number of phenolic hydroxyl groups in the polyphenylene ether can be found, for example, from a standard value of a product of the polyphenylene ether. In addition, examples of the number of terminal hydroxyl groups or the number of terminal phenolic hydroxyl groups include a numerical value representing an average value of hydroxyl groups or phenolic hydroxyl groups per molecule of all polyphenylene ethers present in 1 mol of the polyphenylene ether.

The polyphenylene ether may be used alone or in combination of two or more thereof.

Examples of the polyphenylene ether include a polyphenylene ether including 2,6-dimethylphenol and at least one of bifunctional phenol or trifunctional phenol, and a compound mainly including the polyphenylene ether, such as poly(2,6-dimethyl-1,4-phenylene oxide). More specifically, for example, a compound having a structure represented by Formula (PPE) is preferable.

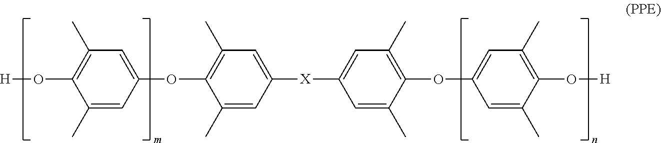

In Formula (PPE), X represents an alkylene group having 1 to 3 carbon atoms or a single bond, m represents an integer of 0 to 20, n represents an integer of 0 to 20, and the sum of m and n represents an integer of 1 to 30.

Examples of the alkylene group in X described above include a dimethylmethylene group.

The compound A is preferably an aromatic polyether ketone.

The aromatic polyether ketone is not particularly limited, and a known aromatic polyether ketone can be used.

The aromatic polyether ketone is preferably a polyether ether ketone.

The polyether ether ketone is one type of the aromatic polyether ketone, and is a polymer in which bonds are arranged in the order of an ether bond, an ether bond, and a carbonyl bond (ketone). It is preferable that the bonds are linked to each other by a divalent aromatic group.

The aromatic polyether ketone may be used alone or in combination of two or more thereof.

Examples of the aromatic polyether ketone include polyether ether ketone (PEEK) having a chemical structure represented by Formula (P1), polyether ketone (PEK) having a chemical structure represented by Formula (P2), polyether ketone ketone (PEKK) having a chemical structure represented by Formula (P3), polyether ether ketone ketone (PEEKK) having a chemical structure represented by Formula (P4), and polyether ketone ether ketone ketone (PEKEKK) having a chemical structure represented by Formula (P5).

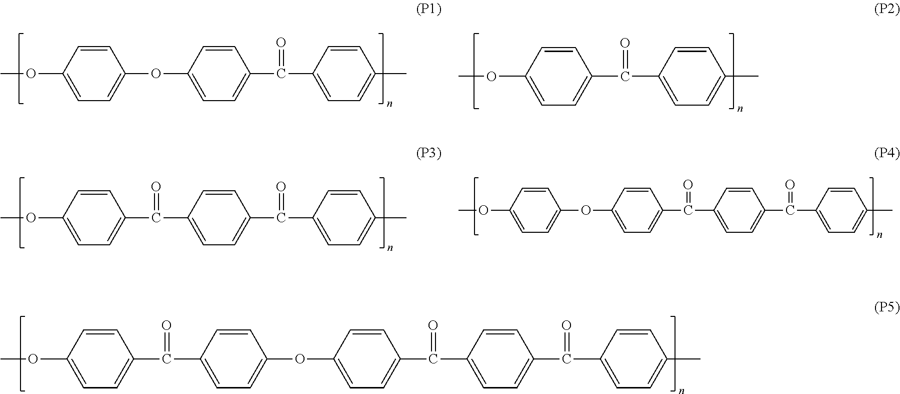

From the viewpoint of mechanical properties, each n of Formulae (P1) to (P5) is preferably 10 or more and more preferably 20 or more. On the other hand, from the viewpoint that the aromatic polyether ketone can be easily produced, n is preferably 5,000 or less and more preferably 1,000 or less. That is, n is preferably 10 to 5,000 and more preferably 20 to 1,000.

Many of the water-soluble resins have an SP value significantly different from the SP value of the liquid crystal polymer, which is suitable as the compound A.

The water-soluble resin preferably has a weight-average molecular weight of 1,000 or more. In addition, a water-soluble compound preferably has a molecular weight of less than 1,000.

The water-soluble resin used as the compound A is not particularly limited, and for example, polyvinyl alcohol, polyacrylamide, polyvinylpyrrolidone, poly(N-vinylacetamide), water-soluble polyester, water-soluble polyurethane, or the like is preferable. Among these, polyvinylpyrrolidone is preferable.

The liquid crystal polymer film may contain only one or two or more kinds of the compounds A.

In a case where the compound A is a solid or a liquid at 25° C., from the viewpoint of low dielectric loss tangent and reduction of volatile components, a content of the compound A in the liquid crystal polymer film is preferably 1% by mass to 90% by mass, more preferably 5% by mass to 80% by mass, and particularly preferably 10% by mass to 70% by mass with respect to the total mass of the liquid crystal polymer film.

In a case where the compound A is a gas at 25° C., from the viewpoint of low dielectric loss tangent and reduction of volatile components, the content of the compound A in the liquid crystal polymer film is preferably 1% by volume to 90% by volume, more preferably 5% by volume to 80% by volume, and particularly preferably 10% by volume to 70% by volume with respect to the total volume of the liquid crystal polymer film.

<Liquid Crystal Polymer>

The liquid crystal polymer film according to the embodiment of the present disclosure contains a liquid crystal polymer (also referred to as “liquid crystal polymer A”).

In the present disclosure, the type of the liquid crystal polymer A is not particularly limited, and a known liquid crystal polymer can be used.

In addition, the liquid crystal polymer A may be a thermotropic liquid crystal polymer which exhibits liquid crystallinity in a molten state, or may be a lyotropic liquid crystal polymer which exhibits liquid crystallinity in a solution state. In addition, in a case of the thermotropic liquid crystal, it is preferable that the liquid crystal is melted at a temperature of 450° C. or lower.

The melting point of the liquid crystal polymer A is a peak temperature, and from the viewpoint that mechanical strength of a web during the manufacturing process is ensured, the melting point thereof is preferably 280° C. or higher, more preferably 300° C. or higher, still more preferably 315° C. or higher, and particularly preferably 330° C. to 400° C.

The melting point is defined as a value measured by a differential scanning calorimetry (DSC) device. 5 mg of a sample is put into a measurement pan of the DSC, and a peak temperature of an endothermic peak which appears in a case where the sample is heated from 30° C. at 10° C./min in a nitrogen stream is defined as the melting point (Tm) of the liquid crystal polymer A.

In a case where a metal layer is laminated on the liquid crystal polymer film, the metal layer is etched and the film is taken out. Subsequently, the film is placed in a measurement pan of DSC for measurement, and among the plurality of appeared endothermic peaks, one which is not derived from the liquid crystal polymer A can be identified and evaluated.

In addition, as another method in a case where the peak does not clearly appear in the DSC measurement, a chemical structure of the liquid crystal polymer A is identified, a plurality of particles including the material are heated to raise the temperature, and a temperature at which the particles are fusion-welded can be evaluated.

Examples of the liquid crystal polymer A include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer A, from the viewpoint of liquid crystallinity and linear expansion coefficient, a polymer having an aromatic ring is preferable, and an aromatic polyester or an aromatic polyester amide is more preferable.

Further, the liquid crystal polymer A may be a polymer in which an imide bond, a carbodiimide bond, a bond derived from an isocyanate, such as an isocyanurate bond, or the like is further introduced into the aromatic polyester or the aromatic polyester amide.

Further, it is preferable that the liquid crystal polymer A is a wholly aromatic liquid crystal polymer formed of only an aromatic compound as a raw material monomer.

Examples of the liquid crystal polymer A include:
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine;
2) a liquid crystal polymer obtained by polycondensing a plurality of types of aromatic hydroxycarboxylic acids;
3) a liquid crystal polymer obtained by polycondensing (i) an aromatic dicarboxylic acid and (ii) at least one compound selected from the group consisting of an aromatic diol, an aromatic hydroxyamine, and an aromatic diamine;
4) a liquid crystal polymer obtained by polycondensing (i) polyester such as polyethylene terephthalate and (ii) an aromatic hydroxycarboxylic acid.

Here, as a part or entire of the aromatic hydroxycarboxylic acid, the aromatic dicarboxylic acid, the aromatic diol, the aromatic hydroxyamine, and the aromatic diamine, each independently, a derivative which can be polycondensed may be used.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid, an aromatic diol, and an aromatic hydroxyamine, include a derivative (acylated product) obtained by acylating a hydroxy group and converting the acylated group into an acyloxy group.

For example, the aromatic hydroxycarboxylic acid, the aromatic diol, and the aromatic hydroxyamine can be each replaced with an acylated product by acylating a hydroxy group and converting the acylated group into an acyloxy group.

Examples of a polymerizable derivative of a compound having an amino group, such as an aromatic hydroxyamine or an aromatic diamine, include a derivative (acylated product) obtained by acylating an amino group and converting the acylated group to an acylamino group.

For example, the aromatic hydroxyamine and the aromatic diamine can be each replaced with an acylated product by acylating an amino group and converting the acylated group into an acylamino group.

From the viewpoint of liquid crystallinity, linear expansion coefficient, and adhesiveness with a metal (a metal foil, a metal wire, or the like), the liquid crystal polymer A preferably has a constitutional unit represented by any of Formulae (1) to (3) (hereinafter, a constitutional unit represented by Formula (1) or the like may be referred to as a constitutional unit (1) or the like), more preferably has a constitutional unit represented by Formula (1), and particularly preferably has a constitutional unit represented by Formula (1), a constitutional unit represented by Formula (2), and a constitutional unit represented by Formula (3).

—O—Ar′—CO— Formula (1)

—CO—Ar²—CO— Formula (2)

—X—Ar³—Y— Formula (3)

In Formulae (1) to (3), Ar¹ represents a phenylene group, a naphthylene group, or a biphenylylene group, Ar² and Ar³ each independently represent a phenylene group, a naphthylene group, a biphenylylene group, or a group represented by Formula (4), X and Y each independently represent an oxygen atom or an imino group, and hydrogen atoms in Ar¹ to Ar³ may be each independently substituted with a halogen atom, an alkyl group, or an aryl group.

—Ar⁴—Z—Ar⁵— Formula (4)

In Formula (4), Ar⁴ and Ary each independently represent a phenylene group or a naphthylene group, and Z represents an oxygen atom, a sulfur atom, a carbonyl group, a sulfonyl group, or an alkylene group.

Examples of the halogen atom include a fluorine atom, a chlorine atom, a bromine atom, and an iodine atom.

Examples of the alkyl group include a methyl group, an ethyl group, an n-propyl group, an isopropyl group, an n-butyl group, an isobutyl group, an s-butyl group, a t-butyl group, an n-hexyl group, a 2-ethylhexyl group, an n-octyl group, and an n-decyl group, and the number of carbon atoms thereof is preferably 1 to 10.

Examples of the aryl group include a phenyl group, an o-tolyl group, an m-tolyl group, a p-tolyl group, a 1-naphthyl group, and a 2-naphthyl group, and the number of carbon atoms thereof is preferably 6 to 20.

In a case where the hydrogen atom is substituted with any of these groups, the number thereof for each group independently represented by Ar¹, Ar², or Ar³ is preferably 2 or less and more preferably 1.

Examples of the alkylene group include a methylene group, a 1,1-ethanediyl group, a 1-methyl-1,1-ethanediyl group, a 1,1-butanediyl group, and a 2-ethyl-1,1-hexanediyl group, and the number of carbon atoms thereof is preferably 1 to 10.

The constitutional unit (1) is a constitutional unit derived from an aromatic hydroxycarboxylic acid.

Preferred examples of the constitutional unit (1) include an aspect in which Ar′ represents a p-phenylene group (constitutional unit derived from p-hydroxybenzoic acid), an aspect in which Ar¹ represents a 2,6-naphthylene group (constitutional unit derived from 6-hydroxy-2-naphthoic acid), and an aspect in which Ar′ represents a 4,4′-biphenylylene group (constitutional unit derived from 4′-hydroxy-4-biphenylcarboxylic acid).

The constitutional unit (2) is a constitutional unit derived from an aromatic dicarboxylic acid.

Preferred examples of the constitutional unit (2) include an aspect in which Ar² represents a p-phenylene group (constitutional unit derived from terephthalic acid), an aspect in which Ar² represents an m-phenylene group (constitutional unit derived from isophthalic acid), an aspect in which Ar² represents a 2,6-naphthylene group (constitutional unit derived from 2,6-naphthalenedicarboxylic acid), and an aspect in which Ar² represents a diphenylether-4,4′-diyl group (constitutional unit derived from diphenylether-4,4′-dicarboxylic acid).

The constitutional unit (3) is a constitutional unit derived from an aromatic diol, an aromatic hydroxylamine, or an aromatic diamine.

Preferred examples of the constitutional unit (3) include an aspect in which Ar³ represents a p-phenylene group (constitutional unit derived from hydroquinone, p-aminophenol, or p-phenylenediamine), an aspect in which Ar³ represents an m-phenylene group (constitutional unit derived from isophthalic acid), and an aspect in which Ar³ represents a 4,4′-biphenyl ylene group (constitutional unit derived from 4,4′-dihydroxybiphenyl, 4-amino-4′-hydroxybiphenyl, or 4,4′-diaminobiphenyl).

A content of the constitutional unit (1) is preferably 30% by mole or more, more preferably 30% to 80% by mole, still more preferably 30% to 60% by mole, and particularly preferably 30% to 40% by mole with respect to the total amount of all constitutional units (a value obtained by dividing the mass of each constitutional unit (also referred to as “monomer unit”) constituting the liquid crystal polymer by the formula weight of each constitutional unit to calculate an amount (mole) equivalent to the substance amount of each constitutional unit and adding up the amounts).

The content of the constitutional unit (2) is preferably 35% by mole or less, more preferably 10% by mole to 35% by mole, still more preferably 20% by mole to 35% by mole, and particularly preferably 30% by mole to 35% by mole with respect to the total amount of all constitutional units.

The content of the constitutional unit (3) is preferably 35% by mole or less, more preferably 10% by mole to 35% by mole, still more preferably 20% by mole to 35% by mole, and particularly preferably 30% by mole to 35% by mole with respect to the total amount of all constitutional units.

The heat resistance, the strength, and the rigidity are likely to be improved as the content of the constitutional unit (1) increases, but the solubility in a solvent is likely to be decreased in a case where the content thereof is extremely large.

A proportion of the content of the constitutional unit (2) to the content of the constitutional unit (3) is expressed as [content of constitutional unit (2)]/[content of constitutional unit (3)] (mol/mol), and is preferably 0.9/1 to 1/0.9, more preferably 0.95/1 to 1/0.95, and still more preferably 0.98/1 to 1/0.98.

The liquid crystal polymer A may have two or more kinds of each of the constitutional units (1) to (3) independently. In addition, the liquid crystal polymer may have a constitutional unit other than the constitutional units (1) to (3), but the content thereof is preferably 10% by mole or less and more preferably 5% by mole or less with respect to the total amount of all the constitutional units.

From the viewpoint of solubility in a solvent, the liquid crystal polymer A preferably has, as the constitutional unit (3), a constitutional unit (3) in which at least one of X or Y is an imino group, that is, preferably has as the constitutional unit (3), at least one of a constitutional unit derived from an aromatic hydroxylamine or a constitutional unit derived from an aromatic diamine, and it is more preferable to have only a constitutional unit (3) in which at least one of X or Y is an imino group.

It is preferable that the liquid crystal polymer A is produced by melt-polymerizing raw material monomers corresponding to the constitutional units constituting the liquid crystal polymer A. The melt polymerization may be carried out in the presence of a catalyst. Examples of the catalyst include metal compounds such as magnesium acetate, stannous acetate, tetrabutyl titanate, lead acetate, sodium acetate, potassium acetate, and antimony trioxide, and nitrogen-containing heterocyclic compounds such as 4-(dimethylamino)pyridine and 1-methylimidazole, and nitrogen-containing heterocyclic compounds are preferably used. The melt polymerization may be further carried out by solid phase polymerization as necessary.

In addition, a weight-average molecular weight of the liquid crystal polymer A is preferably 1,000,000 or less, more preferably 3,000 to 300,000, still more preferably 5,000 to 100,000, and particularly preferably 5,000 to 30,000. In a case where the weight-average molecular weight of the liquid crystal polymer is within the above-described range, a film after heat treatment is excellent in thermal conductivity, heat resistance, strength, and rigidity in the thickness direction.

It is preferable that the liquid crystal polymer A is a liquid crystal polymer that is soluble in a specific organic solvent (hereinafter, also referred to as “soluble liquid crystal polymer”).

Specifically, the soluble liquid crystal polymer in the present disclosure is a liquid crystal polymer in which 0.1 g or more thereof is dissolved at 25° C. in 100 g of at least one solvent selected from the group consisting of N-methylpyrrolidone, N-ethylpyrrolidone, dichloromethane, dichloroethane, chloroform, N,N-dimethylacetamide, γ-butyrolactone, dimethylformamide, ethylene glycol monobutyl ether, and ethylene glycol monoethyl ether.

The liquid crystal polymer film may contain only one or two or more kinds of the liquid crystal polymers A.

From the viewpoint that mechanical strength of a web during the manufacturing process is ensured, a content of the liquid crystal polymer A in the liquid crystal polymer film is preferably 10% by mass to 95% by mass, more preferably 20% by mass to 90% by mass, and particularly preferably 30% by mass to 80% by mass with respect to the total mass of the liquid crystal polymer film.

In a case where the compound A is a solid or a liquid at 25° C., from the viewpoint of low dielectric loss tangent and reduction of volatile components, a mass ratio ML/Mc of a content ML of the liquid crystal polymer A to a content Mc of the compound A in the liquid crystal polymer film is preferably 0.2 to 20, more preferably 0.5 to 10, and particularly preferably 0.8 to 5.

In a case where the compound A is a gas at 25° C., from the viewpoint of low dielectric loss tangent and reduction of volatile components, a volume ratio V^{L}/V^{C} of a volume content V^{L} of the liquid crystal polymer A to a volume content V^{C} of the compound A in the liquid crystal polymer film is preferably 0.1 to 10, more preferably 0.2 to 5, and particularly preferably 0.5 to 2.

<Filler>

From the viewpoint of linear expansion coefficient and adhesiveness with a metal, the liquid crystal polymer film according to the embodiment of the present disclosure preferably contains a filler other than the above-described compound having a dielectric loss tangent of less than 0.01 (hereinafter, also simply referred to as “filler”).

The filler may be particulate or fibrous, and may be an inorganic filler or an organic filler.

In the liquid crystal polymer film according to the embodiment of the present disclosure, from the viewpoint of linear expansion coefficient and adhesiveness with a metal, it is preferable that a number density of the above-described filler is higher inside the above-described liquid crystal polymer film than on the surface of the above-described liquid crystal polymer film.

As the inorganic filler, a known inorganic filler can be used.

Examples of a material of the inorganic filler include BN, Al₂O₃, AlN, TiO₂, SiO₂, barium titanate, strontium titanate, aluminum hydroxide, calcium carbonate, and a material containing two or more of these.

Among these, as the inorganic filler, from the viewpoint of linear expansion coefficient and adhesiveness with a metal, metal oxide particles or fibers are preferable, silica particles, titania particles, or glass fibers are more preferable, and silica particles or glass fibers are particularly preferable.

An average particle diameter of the inorganic filler is preferably approximately 20% to approximately 40% of the thickness of a layer A, and for example, the average particle diameter may be selected from 25%, 30%, or 35% of the thickness of the layer A. In a case where the particles or fibers are flat, the average particle diameter indicates a length in a short side direction.

In addition, from the viewpoint of linear expansion coefficient and adhesiveness with a metal, the average particle diameter of the inorganic filler is preferably 5 nm to 20 μm, more preferably 10 nm to 10 μm, still more preferably 20 nm to 1 μm, and particularly preferably 25 nm to 500 nm.

As the organic filler, a known organic filler can be used.

Examples of a material of the organic filler include polyethylene, polystyrene, urea-formalin filler, polyester, cellulose, acrylic resin, fluororesin, cured epoxy resin, crosslinked benzoguanamine resin, crosslinked acrylic resin, a liquid crystal polymer, and a material containing two or more kinds of these.

In addition, the organic filler may be fibrous, such as nanofibers, or may be hollow resin particles.

Among these, as the organic filler, from the viewpoint of linear expansion coefficient and adhesiveness with a metal, fluororesin particles, polyester-based resin particles, polyethylene particles, liquid crystal polymer particles, or cellulose-based resin nanofibers are preferable, and polytetrafluoroethylene particles, polyethylene particles, or liquid crystal polymer particles are more preferable.

From the viewpoint of linear expansion coefficient and adhesiveness with a metal, an average particle diameter of the organic filler is preferably 5 nm to 20 μm, more preferably 10 nm to 1 μm, still more preferably 20 nm to 500 nm, and particularly preferably 25 nm to 90 nm.

The liquid crystal polymer film may contain only one or two or more kinds of the fillers.

From the viewpoint of linear expansion coefficient and adhesiveness with a metal, the content of the filler in the liquid crystal polymer film is preferably 5% by volume to 80% by volume, more preferably 10% by volume to 70% by volume, still more preferably 15% by volume to 70% by volume, and particularly preferably 20% by volume to 60% by volume with respect to the total volume of the liquid crystal polymer film.

—Other Additives—

The liquid crystal polymer film may contain an additive other than the above-described components.

Known additives can be used as other additives. Specific examples of the other additives include a leveling agent, an antifoaming agent, an antioxidant, an ultraviolet absorbing agent, a flame retardant, and a colorant.

In addition, the liquid crystal polymer film may contain a resin other than the above-described components, as the other additives.

Examples of other resins include thermoplastic resins other than liquid crystal polyester, such as polypropylene, polyamide, polyester other than liquid crystal polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide resin, and a cyanate resin.

The total content of the other additives in the liquid crystal polymer film is preferably 25 parts by mass or less, more preferably 10 parts by mass or less, and still more preferably 5 parts by mass or less with respect to 100 parts by mass of the content of the liquid crystal polymer A.

In addition, the liquid crystal polymer film according to the embodiment of the present disclosure may have a multilayer structure.

For example, the liquid crystal polymer film according to the embodiment of the present disclosure may have a structure which has a layer A containing the liquid crystal polymer and a layer B on at least one surface of the layer A, or may have a structure in which a layer B, a layer A containing the liquid crystal polymer, and a layer C are provided in this order.

From the viewpoint of low dielectric loss tangent and reduction of volatile components, the layer A preferably contains the compound A.

In addition, from the viewpoint of adhesiveness with a metal or other polymer films, it is preferable that the layer B and the layer C each independently do not contain the compound A.

In addition, it is preferable that the layer B and the layer C each independently contain the liquid crystal polymer.

In addition, it is preferable that the polymer contained in the layer B is a polymer having a higher breaking strength (toughness) that the polymer contained in the layer A.

The breaking strength is measured by the following method.

A sample including the polymer to be measured is produced, and using a universal tensile tester “STM T50BP” manufactured by Toyo Baldwin Co., Ltd., a stress against elongation is measured at a tensile rate of 10%/min in an atmosphere of 25° C. and 60% RH to obtain the breaking strength.

Further, examples of a method for detecting or determining a layer configuration of the polymer film, a thickness of each layer, and the like include the following methods.

First, a cross-sectional sample of the polymer film is cut out by a microtome, and a layer configuration and a thickness of each layer are determined with an optical microscope. In a case where the determination with an optical microscope is difficult, the determination may be obtained by performing morphological observation with a scanning electron microscope (SEM), component analysis with a time-of-flight secondary ion mass spectrometry (TOF-SIMS), or the like.

In addition, in a case where the layer B and the layer C are layers which come into contact with the metal layer as a laminate, it is preferable to contain a compound having a functional group, which will be described later, and it is more preferable to contain a compound having a curing reactive group, which will be described later.

The above-described functional group is preferably at least one group selected from the group consisting of a covalent-bondable group, an ion-bondable group, a hydrogen-bondable group, a dipole-interactable group, and a curing reactive group.

The compound having a functional group may be a low-molecular-weight compound or a high-molecular-weight compound.

From the viewpoint of compatibility between the above-described polymer and the compound having a functional group and viewpoint of dielectric loss tangent of the polymer film, the compound having a functional group is preferably a low-molecular-weight compound, and from the viewpoint of heat resistance of the polymer film and mechanical strength, the compound having a functional group is preferably a high-molecular-weight compound.

It is sufficient that the number of functional groups in the compound having a functional group is 1 or more, and the number thereof may be 2 or more.

In addition, the compound having a functional group may have only one kind of functional group, or two or more kinds of functional groups.

From the viewpoint of adhesiveness with a metal, the low-molecular-weight compound used as the compound having a functional group is preferably a compound having a molecular weight of 50 or more and less than 2,000, more preferably a compound having a molecular weight of 100 or more and less than 1,000, and particularly preferably a compound having a molecular weight of 200 or more and less than 1,000.

In addition, from the viewpoint of adhesiveness with a metal, the high-molecular-weight compound used as the compound having a functional group is preferably a polymer having a weight-average molecular weight of 1,000 or more, more preferably a polymer having a weight-average molecular weight of 2,000 or more, still more preferably a polymer having a weight-average molecular weight of 3,000 or more and 1,000,000 or less, and particularly preferably a polymer having a weight-average molecular weight of 5,000 or more and 200,000 or less.

Furthermore, from the viewpoint of dielectric loss tangent of the polymer film and adhesiveness with a metal, it is preferable that the polymer having a dielectric loss tangent of 0.005 or less and the compound having a functional group are compatible with each other.

From the viewpoint of compatibility between the above-described polymer and the compound having a functional group, dielectric loss tangent of the polymer film, and adhesiveness with a metal, a difference between an SP value of the polymer having a dielectric loss tangent of 0.005 or less, which is determined by Hoy method, and an SP value of the compound having a functional group, which is determined by Hoy method, is preferably 5 MPa^{0.5} or less. The lower limit value thereof is 0 MPa^{0.5}.

The solubility parameter value (SP value) determined by Hoy method is calculated from the molecular structure of the resin by the method described in Polymer Handbook fourth edition. In addition, in a case where the resin is a mixture of a plurality of types of resins, the SP value is obtained by calculating an SP value of each constitutional unit.

<<Functional Group>>

The functional group in the compound having a functional group is preferably at least one group selected from the group consisting of a covalent-bondable group, an ion-bondable group, a hydrogen-bondable group, a dipole-interactable group, and a curing reactive group.

From the viewpoint of adhesiveness between the layer C and a metal, the functional group is preferably a covalent-bondable group or a curing reactive group, and more preferably a covalent-bondable group.

In addition, from the viewpoint of storage stability and handleability, the functional group is preferably an ion-bondable group, a hydrogen-bondable group, or a dipole-interactable group.

—Covalent-Bondable Group—

The covalent-bondable group is not particularly limited as long as the group is capable of forming a covalent bond, and examples thereof include an epoxy group, an oxetanyl group, an isocyanate group, an acid anhydride group, a carbodiimide group, a N-hydroxy ester group, a glyoxal group, an imidoester group, a halogenated alkyl group, a thiol group, a hydroxy group, a carboxy group, an amino group, an amide group, an isocyanate group, an aldehyde group, and a sulfonic acid group. Among these, from the viewpoint of adhesiveness between the layer C and a metal, the covalent-bondable group is preferably at least one functional group selected from the group consisting of an epoxy group, an oxetanyl group, an isocyanate group, an N-hydroxy ester group, an isocyanate group, an imidoester group, a halogenated alkyl group, and a thiol group, and particularly preferably an epoxy group.

In addition, as will be described later, it is preferable that the surface of the metal to be bonded to the layer C has a group which is paired with the functional group in the compound having a functional group.

Examples of a combination of the covalent-bondable group and a group which can be paired with the covalent-bondable group (a combination of the functional group in the compound having a functional group and the group present in the surface of the metal) include an aspect in which, for example, in a case where one is an epoxy group or an oxetanyl group, the other is a hydroxy group or an amino group.

Examples thereof also include an aspect in which, for example, in a case where one in the above-described combination is an N-hydroxy ester group or an imidoester group, the other is an amino group.

—Ion-Bondable Group—

Examples of the ion-bondable group include a cationic group and an anionic group.

The above-described cationic group is preferably an onium group. Examples of the onium group include an ammonium group, a pyridinium group, a phosphonium group, an oxonium group, a sulfonium group, a selenonium group, and an iodonium group. Among these, from the viewpoint of adhesiveness between the layer C and a metal, an ammonium group, a pyridinium group, a phosphonium group, or a sulfonium group is preferable, an ammonium group or a phosphonium group is more preferable, and an ammonium group is particularly preferable.

The anionic group is not particularly limited, and examples thereof include a phenolic hydroxyl group, a carboxy group, —SO₃H, —OSO₃H, —POSH, —OPO₃H₂, —CONHSO₂—, and —SO₂NHSO₂—. Among these, a phosphoric acid group, a phosphonic acid group, a phosphinic acid group, a sulfuric acid group, a sulfonic acid group, a sulfinic acid group, or a carboxy group is preferable, a phosphoric acid group or a carboxy group is more preferable, and a carboxy group is still more preferable.

Examples of a combination of the ion-bondable group and a group which can be paired with the ion-bondable group (a combination of the functional group in the compound having a functional group and the group present in the surface of the metal) include an aspect in which, for example, in a case where one is an acidic group, the other is a basic group.

Examples of the above-described acidic group include a carboxy group, a sulfo group, and a phosphoric acid group, and a carboxy group is preferable.

In addition, examples thereof include an aspect in which, for example, in a case where one in the above-described combination is a carboxy group, the ion-bondable group with the carboxy group is a tertiary amino group, a pyridyl group, or a piperidyl group.

—Hydrogen-Bondable Group—

Examples of the hydrogen-bondable group include a group having a hydrogen-bond-donating moiety and a group having a hydrogen-bond-accepting moiety.

It is sufficient that the hydrogen-bond-donating moiety has a structure having an active hydrogen atom capable of hydrogen bonding, and a structure represented by X—H is preferable.

X represents a heteroatom, and is preferably a nitrogen atom or an oxygen atom.

From the viewpoint of adhesiveness between the layer C and a metal, as the above-described hydrogen-bond-donating moiety, at least one structure selected from the group consisting of a hydroxy group, a carboxy group, a primary amide group, a secondary amide group, a primary amino group, a secondary amino group, a primary sulfonamide group, a secondary sulfonamide group, an imide group, a urea bond, and a urethane bond is preferable; at least one structure selected from the group consisting of a hydroxy group, a carboxy group, a primary amide group, a secondary amide group, a primary sulfonamide group, a secondary sulfonamide group, a maleimide group, a urea bond, and a urethane bond is more preferable; at least one structure selected from the group consisting of a hydroxy group, a carboxy group, a primary amide group, a secondary amide group, a primary sulfonamide group, a secondary sulfonamide group, and a maleimide group is still more preferable; and at least one structure selected from the group consisting of a hydroxy group and a secondary amide group is particularly preferable.

The above-described hydrogen-bond-accepting moiety may be a structure containing an atom with an unshared electron pair, and a structure containing an oxygen atom with an unshared electron pair is preferable; at least one structure selected from the group consisting of a carbonyl group (including a carbonyl structure such as a carboxy group, an amide group, an imide group, a urea bond, and a urethane bond) and a sulfonyl group (including a sulfonyl structure such as a sulfonamide group) is more preferable; and a carbonyl group (including a carbonyl structure such as a carboxy group, an amide group, an imide group, a urea bond, and a urethane bond) is particularly preferable.

As the hydrogen-bondable group, a group having both the hydrogen-bond-donating moiety and the hydrogen-bond-accepting moiety described above is preferable; it is preferable to have a carboxy group, an amide group, an imide group, a urea bond, a urethane bond, or a sulfonamide group, and it is more preferable to have a carboxy group, an amide group, an imide group, or a sulfonamide group.

Examples of a combination of the hydrogen-bondable group and a group which can be paired with the hydrogen-bondable group (a combination of the functional group in the compound having a functional group and the group present in the surface of the metal) include an aspect in which, in a case where one is a group having a hydrogen-bond-donating moiety, the other is a group having a hydrogen-bond-accepting moiety.

Examples thereof include an aspect in which, in a case where one in the above-described combination is a carboxy group, the other is an amide group or a carboxy group.

Examples thereof also include an aspect in which, in a case where one in the above-described combination is a phenolic hydroxyl group, the other is a phenolic hydroxide.

—Dipole-Interactable Group—

It is sufficient that the dipole-interactable group is a group having a polarized structure other than the above-described structure represented by X—H (X represents a heteroatom, for example, a nitrogen atom or an oxygen atom) in the hydrogen-bondable group, and suitable examples thereof include a group in which atoms with different electronegativities are bonded to each other.

As a combination of the atoms with different electronegativities, a combination of at least one atom selected from the group consisting of an oxygen atom, a nitrogen atom, a sulfur atom, and a halogen atom, and a carbon atom is preferable; and a combination of at least one atom selected from the group consisting of an oxygen atom, a nitrogen atom, and a sulfur atom, and a carbon atom is more preferable.

Among these, from the viewpoint of adhesiveness between the layer C and a metal, a combination of a nitrogen atom and a carbon atom or a combination of a carbon atom, a nitrogen atom, an oxygen atom, and a sulfur atom is preferable, and specifically, a cyano group, a cyanuric group, or a sulfonic acid amide group is more preferable.

Preferred examples of a combination of the dipole-interactable group and a group which can be paired with the dipole-interactable group (a combination of the functional group in the compound having a functional group and the group present in the surface of the metal) include a combination of identical dipole-interactable groups.

Examples thereof include an aspect in which, in a case where one in the above-described combination is a cyano group, the other is a cyano group.

Examples thereof also include an aspect in which, in a case where one in the above-described combination is a sulfonic acid amide group, the other is a sulfonic acid amide group.

—Curing Reactive Group—

Examples of the curing reactive group include an ethylenically unsaturated group, a cyclic ether group, a cyanato group, a reactive silyl group, an oxazine ring group, and a urethane group.

The following curable compound may be used as the compound having a curing reactive group.

˜Curable Compound˜

The curable compound is a compound which is cured by irradiation with heat or light (for example, visible light, ultraviolet rays, near-infrared rays, far-infrared rays, electron beam, or the like), may require a curing aid described later. Examples of such a curable compound include an epoxy compound, a cyanate ester compound, a vinyl compound, a silicone compound, an oxazine compound, a maleimide compound, an allyl compound, an acrylic compound, a methacrylic compound, and a urethane compound. These may be used alone or in combination of two or more thereof. Among these, from the viewpoint of characteristics such as compatibility with the above-described polymer and heat resistance, at least one selected from the group consisting of an epoxy compound, a cyanate ester compound, a vinyl compound, a silicone compound, an oxazine compound, a maleimide compound, and an allyl compound is preferable; and at least one selected from the group consisting of an epoxy compound, a cyanate ester compound, a vinyl compound, an allyl compound, and a silicone compound is more preferable.

A content of the curable compound in the layer B is preferably 10% by mass or more and 90% by mass or less, and more preferably 20% by mass or more and 80% by mass or less with respect to the total mass of the layer C.

˜Curing Aid˜

Examples of the curing aid include polymerization initiators such as a photoreaction initiator (a photoradical generator, a photoacid generator, or a photobase generator). Specific examples of the curing aid include an onium salt compound, a sulfone compound, a sulfonate compound, a sulfonimide compound, a disulfonyldiazomethane compound, a disulfonylmethane compound, an oximesulfonate compound, a hydrazinesulfonate compound, a triazine compound, a nitrobenzyl compound, a benzylimidazole compound, organic halides, octylic acid metal salt, and disulfone. These curing aids may be used alone or in combination of two or more thereof, regardless of the type.

A content of the curing aid in the layer B is preferably 5% by mass or more and 20% by mass or less, and more preferably 5% by mass or more and 10% by mass or less with respect to the total mass of the layer B.

Specific examples of the bonds or interaction between two kinds of the functional groups are described below, but the bonds or interaction in the present disclosure is not limited thereto.

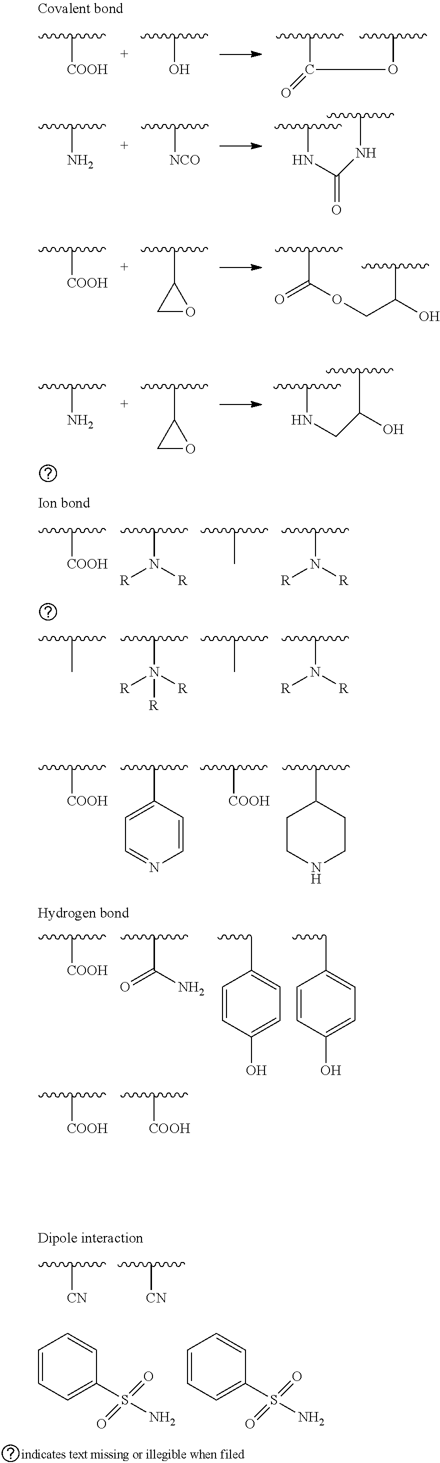

From the viewpoint of dielectric loss tangent of the polymer film and adhesiveness with a metal, the compound having a functional group is preferably a polyfunctional epoxy compound or a polymer of a polyfunctional epoxy compound, more preferably a bifunctional epoxy compound or a polymer of a bifunctional epoxy compound, and particularly preferably a bifunctional epoxy compound.

The layer B or layer C may contain only one or two or more kinds of the compounds having a functional group.

From the viewpoint of dielectric loss tangent of the polymer film and adhesiveness with a metal, a content of the compound having a functional group in the layer B or layer C is preferably 1% by mass to 80% by mass, more preferably 5% by mass to 70% by mass, still more preferably 10% by mass to 60% by mass, and particularly preferably 20% by mass to 60% by mass with respect to the total mass of the polymer film.

An average thickness of the layer A is not particularly limited, but from the viewpoint of linear expansion coefficient and adhesiveness with a metal, the average thickness thereof is preferably 5 μm to 90 μm, more preferably 10 μm to 70 μm, and particularly preferably 15 μm to 50 μm.

A method for measuring the average thickness of each layer in the liquid crystal polymer film according to the embodiment of the present disclosure is as follows.

The thickness of each layer is evaluated by cutting the liquid crystal polymer film with a microtome and observing the cross section with an optical microscope. Three or more sites of the cross-sectional sample are cut out, the thickness is measured at three or more points in each cross section, and the average value thereof is defined as the average thickness.

From the viewpoint of linear expansion coefficient and adhesiveness with a metal, it is preferable that average thicknesses of the layer B and the layer C are each independently smaller than the average thickness of the layer A.

From the viewpoint of linear expansion coefficient and adhesiveness with a metal, a value of T^{A}/T^{B}, which is a ratio of an average thickness T^{A} of the layer A to an average thickness T^{B} of the layer B, is preferably more than 1, more preferably 2 to 100, still more preferably 2.5 to 20, and particularly preferably 3 to 10.

From the viewpoint of linear expansion coefficient and adhesiveness with a metal, a value of T^{A}/T^{C}, which is a ratio of an average thickness T^{A} of the layer A to an average thickness T^{C} of the layer C, is preferably more than 1, more preferably 2 to 100, still more preferably 2.5 to 20, and particularly preferably 3 to 10.

In addition, from the viewpoint of linear expansion coefficient and adhesiveness with a metal, a value of T^{C}/T^{B}, which is a ratio of the average thickness T^{C} of the layer C to the average thickness T^{B} of the layer B, is preferably 0.2 to 5, more preferably 0.5 to 2, and particularly preferably 0.8 to 1.2.

Furthermore, from the viewpoint of linear expansion coefficient and adhesiveness with a metal, the average thicknesses of the layer B and the layer C are each independently preferably 0.1 μm to 20 more preferably 0.5 μm to 15 still more preferably 1 μm to 10 μm, and particularly preferably 3 μm to 8 μm.

From the viewpoint of strength, linear expansion coefficient, and adhesiveness with a metal, an average thickness of the liquid crystal polymer film according to the embodiment of the present disclosure is preferably 6 μm to 200 μm, more preferably 12 μm to 100 μm, and particularly preferably 20 μm to 60 μm.

The average thickness of the liquid crystal polymer film is measured at optional five sites using an adhesive film thickness meter, for example, an electronic micrometer (product name, “KG3001A”, manufactured by Anritsu Corporation), and the average value of the measured values is defined as the average thickness of the polymer film.

From the viewpoint of dielectric constant, the dielectric loss tangent of the liquid crystal polymer film according to the embodiment of the present disclosure is preferably 0.01 or less, more preferably 0.005 or less, still more preferably 0.003 or less, and particularly preferably more than 0 and 0.002 or less.

From the viewpoint of dimensional stability, a linear expansion coefficient of the liquid crystal polymer film according to the embodiment of the present disclosure is preferably −20 ppm/K to 50 ppm/K, more preferably −10 ppm/K to 40 ppm/K, still more preferably 0 ppm/K to 35 ppm/K, and particularly preferably 10 ppm/K to 30 ppm/K.

The linear expansion coefficient in the present disclosure is measured by the following method.

A tensile load of 1 g is applied to both ends of a measurement sample of the liquid crystal polymer film or each layer, which has a width of 5 mm and a length of 20 mm, and a linear expansion coefficient is calculated from the inclination of TMA curve between 30° C. and 150° C. using a thermomechanical analyzer (TMA) in a case where the temperature is raised from 25° C. to 200° C. at a rate of 5° C./min, lowered to 30° C. at a rate of 20° C./min, and raised again at a rate of 5° C./min.

In a case where each layer is measured, a measurement sample may be produced by scraping off the layer to be measured with a razor or the like.

In addition, in a case where it is difficult to measure the linear expansion coefficient by the above-described method, the measurement is carried out by the following method.

The liquid crystal polymer film is cut with a microtome to produce a section sample, and the section sample is set in an optical microscope equipped with a heating stage system (HS82, manufactured by METTLER TOLEDO). Subsequently, the section sample was heated from 25° C. to 200° C. at a rate of 5° C./min, cooled to 30° C. at a rate of 20° C./min, and then heated again at a rate of 5° C./min, and a thickness of the liquid crystal polymer film or each layer at 30° C. (ts30) and a thickness of the liquid crystal polymer film or each layer at 150° C. (ts150) are evaluated. Thereafter, a value obtained by dividing the dimensional change by the temperature change ((ts150−ts30)/(150−30)) may be calculated to obtain the linear expansion coefficient of the liquid crystal polymer film or each layer.

<Method for Manufacturing Liquid Crystal Polymer Film>

A method for manufacturing the liquid crystal polymer film according to the embodiment of the present disclosure is not particularly limited, and a known method can be referred to.

[Film Formation]

Suitable examples of the method for manufacturing the liquid crystal polymer film according to the embodiment of the present disclosure include a casting method, a coating method, and an extrusion method. Among these, a casting method is particularly preferable. In addition, in a case where the polymer film according to the embodiment of the present disclosure has a multilayer structure, suitable examples thereof include a co-casting method, a multilayer coating method, and a co-extrusion method. Among these, the co-casting method is particularly preferable for formation of a relatively thin film, and the co-extrusion method is particularly preferable for formation of a thick film.

In a case where the multilayer structure in the polymer film is manufactured by the co-casting method or the multilayer coating method, it is preferable that the co-casting method or the multilayer coating method is performed by using a composition for forming the layer A, a composition for forming the layer B, a composition for forming the layer C, or the like obtained by dissolving or dispersing components of each layer, such as the liquid crystal polymer A and the compound having a dielectric loss tangent of less than 0.01, in a solvent.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and γ-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Among these, two or more kinds thereof may be used in combination.

The solvent preferably contains an aprotic compound (particularly, an aprotic compound having no halogen atom) for low corrosiveness and easiness to handle. A proportion of the aprotic compound to the whole solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, it is preferable to contain an amide such as N,N-dimethylformamide, N,N-dimethylacetamide, tetramethylurea, and N-methylpyrrolidone, or an ester such as γ-butyrolactone; and it is more preferable to contain N,N-dimethylformamide, N,N-dimethylacetamide, or N-methylpyrrolidone.

In addition, as the solvent, it is preferable to contain a compound having a dipole moment of 3 to 5, because the liquid crystal polymer can be easily dissolved. A proportion of the compound having a dipole moment of 3 to 5 to the whole solvent is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, it is preferable to contain a compound having a boiling point of 220° C. or lower at 1 atm, because the solvent is easily removed. A proportion of the compound having a boiling point of 220° C. or lower at 1 atm to the whole solvent is preferably 50% by mass to 100% by mass, more preferably 70% by mass to 100% by mass, and particularly preferably 90% by mass to 100% by mass.

It is preferable to use the compound having a boiling point of 220° C. or lower at 1 atm as the above-described aprotic compound.

In addition, in a case where the liquid crystal polymer film is manufactured by the co-casting method, the multilayer coating method, the co-extrusion method, or the like, a support may be used in the method for manufacturing the liquid crystal polymer film according to the embodiment of the present disclosure. In addition, in a case where the metal layer (metal foil) or the like used in the laminate described later is used as the support, the support may be used as it is without being peeled off.

Examples of the support include a metal drum, a metal band, a glass plate, a resin film, and a metal foil. Among these, a metal drum, a metal band, or a resin film is preferable.

Examples of the resin film include a polyimide (PI) film, and examples of commercially available products thereof include U-PILEX S and U-PILEX R (manufactured by Ube Corporation), KAPTON (manufactured by Du Pont-Toray Co., Ltd.), and IF30, IF70, and LV300 (manufactured by SKC Kolon PI, Inc.).

In addition, the support may have a surface treatment layer formed on the surface so that the support can be easily peeled off. Hard chrome plating, a fluororesin, or the like can be used as the surface treatment layer.

An average thickness of the resin film support is not particularly limited, but is preferably 25 μm or more and 75 μm or less and more preferably 50 μm or more and 75 μm or less.

In addition, a method for removing at least a part of the solvent from a cast or applied film-like composition (a casting film or a coating film) is not particularly limited, and a known drying method can be used.

[Stretching]

In the method for manufacturing the liquid crystal polymer film according to the embodiment of the present disclosure, stretching can be combined as appropriate from the viewpoint of controlling molecular alignment and adjusting linear expansion coefficient and mechanical properties. A stretching method is not particularly limited, and a known method can be referred to. The stretching may be carried out on a film in a solvent-containing state or on a dry film. The stretching of the film in a solvent-containing state may be carried out by gripping and stretching the film in a solvent-containing state, may be carried out by utilizing a self-contractile force of a web due to drying the film in a solvent-containing state without stretching, or may be carried out by combining these methods. The stretching is particularly effective for the purpose of improving the breaking elongation and the breaking strength, in a case where brittleness of the film is reduced by addition of an inorganic filler or the like.

In addition, the method for manufacturing the liquid crystal polymer film according to the embodiment of the present disclosure may include other known steps as necessary.

In addition, in the method for manufacturing the liquid crystal polymer film according to the embodiment of the present disclosure, a foaming agent may be used to form voids.

The foaming agent is not particularly limited, and a known foaming agent can be used. The foaming agent may be a physical foaming agent or a chemical foaming agent.

The chemical foaming agent may be an inorganic compound or an organic compound, and two or more kinds thereof may be used in combination.

Examples of the organic chemical foaming agent include a nitrosamine compound such as dinitroso pentamethylene tetramine (DPT), an azo compound such as azodicarbonamide (ADCA), and a hydrazine compound such as 4,4′-oxybisbenzenesulfonyl hydrazide (OBSH) and hydrazodicarbonamide (HDCA).

Examples of the inorganic chemical foaming agent include a hydrogen carbonate such as sodium hydrogen carbonate, a carbonate, and a combination of a hydrogen carbonate and an organic acid salt such as sodium citrate.

Examples of the physical foaming agent include carbon dioxide and nitrogen, which are liquid, solid, or supercritical fluids.

In addition, from the viewpoint of low dielectric loss tangent and reduction of volatile components, it is preferable that the method for manufacturing the liquid crystal polymer film according to the embodiment of the present disclosure includes a casting step of extruding a composition containing the liquid crystal polymer and a solvent A onto a support to produce a casting film, a liquid immersion step of immersing the casting film in a solvent B having a boiling point lower than a melting point of the liquid crystal polymer, and a drying step of removing at least a part of the solvent B contained in the casting film.

—Casting Step—

From the viewpoint of low dielectric loss tangent and reduction of volatile components, the method for manufacturing the liquid crystal polymer film according to the embodiment of the present disclosure preferably includes a casting step of extruding a composition containing the above-described liquid crystal polymer and a solvent A onto a support to produce a casting film.

A casting method in the casting step is not particularly limited, and a known casting method can be used.

As the solvent A used in the casting step, the above-described solvent can be suitably used.

In addition, in a case of using a void-forming agent described later, an aqueous solvent may be used in combination as the solvent A.

As the support used in the casting step, the above-described support can be suitably used.

The casting speed, casting time, thickness of the casting film to be formed, and the like in the casting step are not particularly limited, and can be appropriately set.

In addition, the method for manufacturing the liquid crystal polymer film according to the embodiment of the present disclosure may include, between the casting step and the liquid immersion step, a step of removing at least a part of the above-described solvent A contained in the above-described casting film.

—Liquid Immersion Step—

The method for manufacturing the liquid crystal polymer film according to the embodiment of the present disclosure preferably includes a liquid immersion step of immersing the above-described casting film in a solvent B having a boiling point lower than a melting point of the above-described liquid crystal polymer.

The solvent B used in the casting step may be any solvent having a boiling point lower than the melting point of the above-described liquid crystal polymer, but a solvent having a low solubility of the above-described liquid crystal polymer is preferable.

The solvent B is preferably a solvent in which the liquid crystal polymer used is not dissolved or is dissolved less than 0.1 g in 100 g of the solvent at 25° C., more preferably a solvent in which the liquid crystal polymer used is not dissolved or is dissolved less than 0.01 g in 100 g of the solvent at 25° C., and particularly preferably a solvent in which the liquid crystal polymer used is not dissolved in 100 g of the solvent at 25° C.

In addition, in a case where the liquid crystal polymer film contains a void-forming agent, that is, in a case where the above-described composition contains a void-forming agent, from the viewpoint of void formation and low dielectric loss tangent, the solvent B is preferably a solvent capable of dissolving the void-forming agent, and more preferably a solvent in which the void-forming agent is dissolved 0.1 g or more in 100 g of the solvent at 25° C.

From the viewpoint of void formation and incompatibility with the liquid crystal polymer, the void-forming agent is preferably a water-soluble compound and more preferably a water-soluble resin.

As the water-soluble compound, a known water-soluble compound can be used, and preferred examples thereof include the above-described water-soluble resin as the compound A.

In a case of using the void-forming agent, the solvent B is preferably an aqueous solvent, preferably water, alcohols, or a mixed solvent thereof, more preferably water or a mixed solvent of water and alcohols, and particularly preferably water.

The immersion temperature, immersion time, amount of the solvent B to be used, and the like in the liquid immersion step are not particularly limited, and can be appropriately set.

—Drying Step—

The method for manufacturing the liquid crystal polymer film according to the embodiment of the present disclosure preferably includes a drying step of removing at least a part of the solvent B contained in the casting film.

A drying unit in the drying step is not particularly limited, and a known drying unit can be used.

The drying temperature and drying time in the drying step are not particularly limited, and can be appropriately set depending on the boiling point of the solvent B, and the like.

In addition, the method for manufacturing the liquid crystal polymer film according to the embodiment of the present disclosure may include, as necessary, other known steps after the drying step, such as the above-described stretching.

[Heat Treatment]

The method for manufacturing the polymer film according to the embodiment of the present disclosure preferably includes a step of heat-treating (annealing) the polymer film.

Specifically, from the viewpoint of dielectric loss tangent and peel strength, the heat treatment temperature in the above-described step of heat-treating is preferably 260° C. to 370° C., more preferably 280° C. to 360° C., and still more preferably 300° C. to 350° C. The heat treatment time is preferably 15 minutes to 10 hours and more preferably 30 minutes to 5 hours. In addition, in a case where the material is decomposed or discolored during the heat treatment, a method such nitrogen purging and addition of a known deterioration inhibitor can be appropriately combined.

In addition, the method for manufacturing the polymer film according to the embodiment of the present disclosure may include other known steps as necessary.

<Applications>

The liquid crystal polymer film according to the embodiment of the present disclosure can be used for various applications. Among the various applications, the liquid crystal polymer film can be used suitably as a film for an electronic component such as a printed wiring board and more suitably for a flexible printed circuit board.

In addition, the liquid crystal polymer film according to the embodiment of the present disclosure can be suitably used as a liquid crystal polymer film for metal adhesion.

(Laminate)

The laminate according to the embodiment of the present disclosure may be one in which the liquid crystal polymer film according to the embodiment of the present disclosure is laminated, but it is preferable to include the liquid crystal polymer film according to the embodiment of the present disclosure and a metal layer disposed on at least surface of the liquid crystal polymer film, and it is more preferable to include the liquid crystal polymer film according to the embodiment of the present disclosure and metal layers respectively disposed on both surfaces of the liquid crystal polymer film. In addition, it is more preferable that the metal layer is a copper layer.

The laminate according to the embodiment of the present disclosure preferably includes the liquid crystal polymer film according to the embodiment of the present disclosure including the layer A and the layer B on at least one surface of the layer A, and a copper layer disposed on the surface of the above-described layer B side.

The metal layer disposed on the surface of the above-described layer B side is preferably a metal layer disposed on the surface of the above-described layer B.

In addition, from the viewpoint of interlaminar adhesion, it is preferable that a thickness of the above-described layer B is larger than a thickness of the metal layer (preferably, the copper layer).

Further, a peel strength between the above-described layer B and the above-described copper layer is preferably 0.5 kN/m or more, more preferably 0.7 kN/m or more, still more preferably 0.7 kN/m to 2.0 kN/m, and particularly preferably 0.9 kN/m to 1.5 kN/m.

It is preferable that the laminate according to the embodiment of the present disclosure further includes the layer C, that is, the laminate according to the embodiment of the present disclosure includes the liquid crystal polymer film according to the embodiment of the present disclosure including the above-described layer B, the above-described layer A, and the above-described layer C in this order, and a copper layer disposed on the surface of the above-described layer C side.

In addition, from the viewpoint of interlaminar adhesion, it is preferable that a thickness of the above-described layer C is larger than a thickness of the metal layer (preferably, the copper layer).

It is preferable that the metal layer disposed on the surface of the above-described layer C side is a metal layer disposed on the surface of the above-described layer C, and it is more preferable that the metal layer disposed on the surface of the above-described layer B side is a metal layer disposed on the surface of the above-described layer B, and the metal layer disposed on the surface of the above-described layer C side is a metal layer disposed on the surface of the above-described layer C.

Furthermore, a peel strength between the above-described layer C and the above-described copper layer is preferably 0.5 kN/m or more, more preferably 0.7 kN/m or more, still more preferably 0.7 kN/m to 2.0 kN/m, and particularly preferably 0.9 kN/m to 1.5 kN/m.

In addition, the metal layer disposed on the surface of the above-described layer B side and the metal layer disposed on the surface of the above-described layer C side may be a metal layer having the same material, thickness, and shape, or may be metal layers having different materials, thicknesses, and shapes. From the viewpoint of adjusting the characteristic impedance, the metal layer disposed on the surface of the above-described layer B side and the metal layer disposed on the surface of the above-described layer C side may be metal layers having different materials or thicknesses, or a metal layer may be laminated on only one side of the layer B or the layer C.

Furthermore, from the viewpoint of adjusting the characteristic impedance, preferred examples thereof also include an aspect in which a metal layer is laminated on one side of the layer B or the layer C, and another polymer film (preferably, another liquid crystal polymer film) is laminated on the other side.

A method of attaching the polymer film according to the embodiment of the present disclosure to the metal layer is not particularly limited, and a known laminating method can be used.

A peel strength between the above-described liquid crystal polymer film and the above-described copper layer is preferably 0.5 kN/m or more, more preferably 0.7 kN/m or more, still more preferably 0.7 kN/m to 2.0 kN/m, and particularly preferably 0.9 kN/m to 1.5 kN/m.

In the present disclosure, the peel strength between the liquid crystal polymer film and the metal layer (for example, the copper layer) is measured by the following method.

A peeling test piece with a width of 1.0 cm is produced from the laminate of the liquid crystal polymer film and the metal layer, the liquid crystal polymer film is fixed to a flat plate with double-sided adhesive tape, and the strength (kN/m) in a case of peeling the liquid crystal polymer film off from the metal layer at a rate of 50 mm/min is measured by the 180° method in conformity with JIS C 5016 (1994).

In a case of not including the layer C containing the above-described compound having a curing reactive group, a surface roughness Rz of the above-described metal layer on the side in contact with the above-described polymer film is preferably 1 μm to 10 μm, more preferably 1 μm to 5 μm, and particularly preferably 1.5 μm to 3 μm. In addition, in a case of including the layer C containing the above-described compound having a curing reactive group, from the viewpoint of transmission loss proposal of high-frequency signals, the surface roughness Rz thereof is preferably less than 1 μm, more preferably 0.5 μm or less, and particularly preferably 0.3 μm or less.

The “surface roughness Rz” in the present disclosure refers to a value expressed in micrometer, which is the total value of the maximum value of height of peak and the maximum value of depth of valley observed on a roughness curve over the reference length.

In the present disclosure, the surface roughness Rz of the metal layer (for example, the copper layer) is measured by the following method.

Using a noncontact surface/layer cross-sectional shape measurement system VertScan (manufactured by MITSUBISHI CHEMICAL SYSTEMS, Inc.), a square of 465.48 μm in length and 620.64 μm in width is measured to create a roughness curve on the surface of the measurement object (metal layer) and create an average line of the roughness curve. A portion corresponding to the reference length is extracted from the roughness curve. The surface roughness Rz of the measurement object is measured by obtaining the total value of the maximum value of height of peak (that is, height from the average line to summit) and the maximum value of depth of valley (that is, height from the average line to valley bottom) observed in the extracted roughness curve.

The metal layer is preferably a copper layer. As the copper layer, a rolled copper foil formed by a rolling method or an electrolytic copper foil formed by an electrolytic method is preferable, and a rolled copper foil is more preferable from the viewpoint of bending resistance.

An average thickness of the metal layer, preferably the copper layer, is not particularly limited, but is preferably 2 μm to 20 μm, more preferably 3 μm to 18 μm, and still more preferably 5 μm to 12 μm. The copper foil may be copper foil with a carrier formed on a support (carrier) so as to be peelable. As the carrier, a known carrier can be used. An average thickness of the carrier is not particularly limited, but is preferably 10 μm to 100 μm and more preferably 18 μm to 50 μm.

The metal layer in the laminate according to the embodiment of the present disclosure may be a metal layer having a circuit pattern.

It is also preferable that the metal layer in the laminate according to the embodiment of the present disclosure is processed into, for example, a desired circuit pattern by etching to form a flexible printed circuit board. The etching method is not particularly limited, and a known etching method can be used.

### EXAMPLES

Hereinafter, the present disclosure will be described in more detail with reference to examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

<<Measurement Method>>

[Dielectric Loss Tangent]

A dielectric constant was measured by a resonance perturbation method at a frequency of 10 GHz. A 10 GHz cavity resonator (CP531 manufactured by Kanto Electronics Application & Development Inc.) was connected to a network analyzer (“E8363B” manufactured by Agilent Technology), a sample (width: 2 mm x length: 80 mm) was inserted into the cavity resonator, and the dielectric constant and dielectric loss tangent of the sample were measured based on a change in resonance frequency for 96 hours before and after the insertion in an environment of a temperature of 25° C. and a humidity of 60% RH.

[Volatile Component Content]

A sample was weighed by conditioning at 25° C. and a relative humidity of 60% (mass W0), and then weighed by being heated at 300° C. for 1 hour and conditioning at 25° C. and a relative humidity of 60% (mass W1). Thereafter, W1/W0×100 [%] was defined as a volatile component content (% by mass).

### Production Example

<Liquid Crystal Polymer>

LC-A: Liquid crystal polymer produced by production method described below

—Production of LC-A—

940.9 g (5.0 mol) of 6-hydroxy-2-naphthoic acid, 377.9 g (2.5 mol) of 4-hydroxyacetaminophen, 415.3 g (2.5 mol) of isophthalic acid, and 867.8 g (8.4 mol) of acetic acid anhydride were added to a reactor provided with a stirrer, a torque meter, a nitrogen gas introduction pipe, a thermometer, and a reflux condenser, the gas inside the reactor was replaced with nitrogen gas, and the mixture was heated from room temperature (23° C.) to 140° C. over 60 minutes while being stirred in a nitrogen gas stream and was refluxed at 140° C. for 3 hours.

Thereafter, the mixture was heated from 150° C. to 300° C. over 5 hours while distilling off by-product acetic acid and unreacted acetic acid anhydride and maintained at 300° C. for 30 minutes, and the resultant was taken out from the reactor and cooled to room temperature. The obtained solid matter was crushed with a crusher, thereby obtaining powdery liquid crystal polyester (B1). The flow start temperature of the liquid crystal polyester (B1) was 193.3° C.

The liquid crystal polyester (B1) obtained above was heated from room temperature to 160° C. over 2 hours and 20 minutes in a nitrogen atmosphere, further heated from 160° C. to 180° C. over 3 hours and 20 minutes, maintained at 180° C. for 5 hours to carry out solid phase polymerization, cooled, and crushed with a crusher, thereby obtaining powdery liquid crystal polyester (B2). The flow start temperature of the liquid crystal polyester (B2) was 220° C.

The liquid crystal polyester (B2) obtained above was heated from room temperature (23° C.) to 180° C. over 1 hour and 25 minutes in a nitrogen atmosphere, further heated from 180° C. to 255° C. over 6 hours and 40 minutes, maintained at 255° C. for 5 hours to carry out solid phase polymerization, and cooled, thereby obtaining powdery liquid crystal polyester (LC-A). A flow start temperature of LC-A was 302° C. In addition, as a result of measuring a melting point of the LC-A using a differential scanning calorimetry device, the measured value was 311° C.

LC-B: Liquid crystal polymer produced by production method described below

—Production of LC-B—

941 g (5.0 mol) of 6-hydroxy-2-naphthoic acid, 273 g (2.5 mol) of 4-aminophenol, 415 g (2.5 mol) of isophthalic acid, and 1123 g (11 mol) of acetic acid anhydride were added to a reactor provided with a stirrer, a torque meter, a nitrogen gas introduction pipe, a thermometer, and a reflux condenser, the gas inside the reactor was replaced with nitrogen gas, and the mixture was heated from room temperature (23° C.) to 150° C. over 15 minutes while being stirred in a nitrogen gas stream and was refluxed at 150° C. for 3 hours.

Thereafter, the mixture was heated from 150° C. to 320° C. over 3 hours while distilling off by-product acetic acid and unreacted acetic acid anhydride and maintained until an increase in viscosity was observed, and the resultant was taken out from the reactor and cooled to room temperature. The obtained solid matter was crushed with a crusher, thereby obtaining powdery liquid crystal polyester (B1).

The liquid crystal polyester (B1) obtained above was maintained at 250° C. for 3 hours in a nitrogen atmosphere to carry out solid phase polymerization, cooled, and crushed with a crusher, thereby obtaining powdery liquid crystal polyester (LC-B).

<Compound A>
A-1: Commercially available polyvinylpyrrolidone (K-30, manufactured by NIPPON SHOKUBAI CO., LTD., water-soluble resin)
A-2: Commercially available polyethylene particles (FLO-BEADS CL-2080, manufactured by SUMITOMO SEIKA CHEMICALS CO., LTD.)

### Examples 1 to 9 and Comparative Example 1

<Film Formation>

A film was formed according to the following casting.

[Casting A (Solution Film Formation)]

—Preparation of Polymer Solution—

The liquid crystal polymer shown in Table 1 was added to N-methylpyrrolidone (boiling point: 202° C.) and stirred at 140° C. for 4 hours in a nitrogen atmosphere to form a solution. Thereafter, the compound A shown in Table 1 was added to the solution such that the mass ratio was as shown in Table 1, the mixture was stirred at 25° C. for 30 minutes, and then 0.5 parts by mass of lithium chloride and 3 parts by mass of water were added thereto and stirred to form a liquid crystal polymer solution. The concentration of solid contents was 30% by mass.

Subsequently, first, the solution was allowed to pass through a sintered fiber metal filter having a nominal pore diameter of 10 μm and allowed to pass through a sintered fiber metal filter having the same nominal pore diameter of 10 μm, thereby obtaining a polymer solution.

—Production of Film—

The obtained polymer solution was fed to a casting die, cast onto a temporary support of polyethylene terephthalate (PET), blown with air adjusted to 25° C. and a relative humidity of 40%, and then immediately immersed in a coagulation bath filled with water at 25° C. Subsequently, the temporary support was peeled off, and the film was dried at 100° C. to obtain a liquid crystal polymer film.

[Casting B (Solution Film Formation)]

—Preparation of Polymer Solution—

The liquid crystal polymer shown in Table 1 was added to N-methylpyrrolidone (boiling point: 202° C.) and stirred at 140° C. for 4 hours in a nitrogen atmosphere to form a solution. Thereafter, the compound A shown in Table 1 was added to the solution such that the mass ratio was as shown in Table 1, the mixture was stirred at 25° C. for 30 minutes, and then 0.5 parts by mass of lithium chloride and 3 parts by mass of water were added thereto and stirred to form a liquid crystal polymer solution. The concentration of solid contents was 30% by mass.

—Production of Film—

The obtained polymer solution was fed to a casting die, cast onto a temporary support of polyethylene terephthalate (PET), blown with air adjusted to 25° C. and a relative humidity of 50%, and then immediately immersed in a coagulation bath filled with water at 25° C. Subsequently, the temporary support was peeled off, and the film was washed with a diethylene glycol solution at 80° C. for 2 minutes and then with pure water at 70° C. for 5 minutes. Further, the film was dried at 80° C. to obtain a liquid crystal polymer film.

<Production of Copper-Clad Laminated Plate>

—Copper-Clad Laminated Plate Precursor Step—

A copper foil (manufactured by FUKUDA METAL FOIL & POWER CO., LTD., CF-T4X-SV-12, thickness: 12 μm) was placed on the liquid crystal polymer film of Example 3 such that a treated surface of the copper foil was in contact with a surface of the temporary support side of the liquid crystal polymer film, and using a laminator (“Vacuum laminator V-130” manufactured by Nikko-Materials Co., Ltd.), lamination was performed for 1 minute under conditions of 140° C. and a laminating pressure of 0.4 MPa. Subsequently, using a thermocompression machine (“MP-SNL” manufactured by Toyo Seiki Seisaku-sho, Ltd.), the obtained copper-clad laminated plate precursor was subjected to thermocompression under conditions of 300° C. and 4.5 MPa for 10 minutes to produce a copper-clad laminated plate. The produced copper-clad laminated plate was excellent in adhesiveness between the copper foil and the liquid crystal polymer film layer, and was free of air bubbles and the like. Further, the obtained copper-clad laminated plate was heated in a nitrogen atmosphere from room temperature to 270° C. at 1° C./min, and a heat treatment was performed at the temperature for 2 hours to obtain a copper-clad laminated plate.

On the other hand, in a case where the liquid crystal polymer film of Comparative Example 1 was used, defects of air bubbles were confirmed between the copper foil and the liquid crystal polymer layer.

[Casting C (Solution Film Formation)]

—Preparation of Polymer Solution—

The polymer shown in Table 1 and the additive shown in Table 1 were added to N-methylpyrrolidone, and the mixture was stirred at 140° C. for 4 hours in a nitrogen atmosphere, thereby obtaining a polymer solution. The above-described polymer and additive were added in the volume ratios shown in Table 1, and the concentration of solid contents was set to the values shown in Table 1.

Subsequently, first, the solution was allowed to pass through a sintered fiber metal filter having a nominal pore diameter of 10 μm and allowed to pass through a sintered fiber metal filter having the same nominal pore diameter of 10 μm, thereby obtaining a liquid crystal polymer solution.

In a case where the additive was not dissolved in N-methylpyrrolidone, a liquid crystal polymer solution was prepared without adding the additive, the mixture was allowed to pass through the above-described sintered fiber metal filter, and then the additive was added thereto and stirred.

—Production of Film—

The obtained liquid crystal polymer solution was fed to a casting die and cast onto a roughened surface of a copper foil (manufactured by FUKUDA METAL FOIL & POWER CO., LTD., CF-T4X-SV-12, thickness: 12 μm) as a support. The casting film was dried at 40° C. for 4 hours to remove the solvent from the casting film. Thereafter, under a nitrogen atmosphere, a heat treatment was performed at 270° C. for 2 hours, and then the casting film was quenched by immersion in a water bath and dried at 100° C. to obtain a copper-clad laminated plate having a liquid crystal polymer film.

<<Evaluation>>

The produced liquid crystal polymer film was evaluated by the methods described above, and the results are shown in Table 1.

TABLE 1

| | Liquid crystal polymer film | | | | | | | |
|---|---|---|---|---|---|---|---|---|
| | Liquid crystal | | | | | | Evaluation result | |
| | polymer | | Compound A | | | | Liquid polymer film | |
| | | Used | | Used | | | | Residue |
| | | amount | | amount | | Film | | solvent |
| | | (% by | | (% by | Average | formation | Dielectric | (% by |
| | Type | mass) | Type | mass ) | thickness | method | loss tangent | mass) |
| Example 1 | LC-A | 40 | A-1 | 60 | 100 μm | Casting A | 0.001 | <0.1 |
| Example 2 | LC-A | 50 | A-1 | 40 | 100 μm | Casting A | 0.002 | <0.1 |
| Example 3 | LC-A | 60 | A-1 | 30 | 100 μm | Casting A | 0.002 | <0.1 |
| Example 4 | LC-A | 60 | A-1 | 40 | 100 μm | Casting B | 0.002 | <0.1 |
| Example 5 | LC-A | 60 | A-1 | 40 | 75 μm | Casting B | 0.002 | <0.1 |
| Example 6 | LC-A | 60 | A-1 | 40 | 50 μm | Casting B | 0.002 | <0.1 |
| Example 7 | LC-B | 60 | A-1 | 40 | 50 μm | Casting B | 0.002 | <0.1 |
| Example 8 | LC-A | 50 | A-1 | 50 | 100 μm | Casting B | 0.002 | <0.1 |
| Example 9 | LC-A | 65 | A-2 | 35 | 50 μm | Casting C | 0.004 | <0.1 |
| Comparative | LC-A | 100 | — | 0 | 100 μm | Casting A | 0.006 | 3 |
| Example 1 | | | | | | | | |

With regard to the liquid crystal polymer films of Examples 1 to 9, in a gyroid structure (also called double-connected structure; a type of the interpenetrating network structure) consisting of the liquid crystal polymer and the compound A, portions of the compound A were displaced into voids by elution of the compound A into water.

From the results shown in Table 1, the liquid crystal polymer films of Examples 1 to 9, which are the liquid crystal polymer film according to the embodiment of the present disclosure, had a lower volatile component content than the liquid crystal polymer film of Comparative Example 1.

In addition, from the results shown in Table 1, the liquid crystal polymer films of Examples 1 to 9, which are the liquid crystal polymer film according to the embodiment of the present disclosure, were a liquid crystal polymer film having a low dielectric loss tangent.

The disclosure of Japanese Patent Application No. 2020-197563 filed on Nov. 27, 2020 is incorporated in the present specification by reference.

All documents, patent applications, and technical standards described in the present specification are incorporated herein by reference to the same extent as in a case of being specifically and individually noted that individual documents, patent applications, and technical standards are incorporated by reference.

What is claimed is:

1. A liquid crystal polymer film comprising:
a liquid crystal polymer,
wherein the liquid crystal polymer film includes a portion where a density of the liquid crystal polymer is low and a portion where the density of the liquid crystal polymer is high.

2. The liquid crystal polymer film according to claim 1,
wherein the portion where the density of the liquid crystal polymer is low includes a void.

3. The liquid crystal polymer film according to claim 1,
wherein the portion where the density of the liquid crystal polymer is low and the portion where the density of the liquid crystal polymer is high have an interpenetrating network structure, a cylinder structure, a lamella structure, or a sea-island structure.

4. A liquid crystal polymer film comprising:
a liquid crystal polymer; and
a compound incompatible with the liquid crystal polymer.

5. A liquid crystal polymer film comprising:
a liquid crystal polymer; and
a compound A,
wherein an absolute value of a difference between an SP value of the liquid crystal polymer, which is determined by Hoy method, and an SP value of the compound A, which is determined by Hoy method, is 0.1 MPa^{0.5} or more.

6. The liquid crystal polymer film according to claim 1,
wherein the liquid crystal polymer film includes a layer A and a layer B on at least one surface of the layer A.

7. The liquid crystal polymer film according to claim 6,
wherein the liquid crystal polymer film further includes a layer C, and
the layer B, the layer A, and the layer C are provided in this order.

8. The liquid crystal polymer film according to claim 1,
wherein a linear expansion coefficient of the liquid crystal polymer film is −20 ppm/K to 50 ppm/K.

9. The liquid crystal polymer film according to claim 1,
wherein a dielectric loss tangent of the liquid crystal polymer film is 0.01 or less.

10. The liquid crystal polymer film according to claim 1, further comprising:
a filler.

11. The liquid crystal polymer film according to claim 10,
wherein a number density of the filler is higher inside the liquid crystal polymer film than on a surface of the liquid crystal polymer film.

12. The liquid crystal polymer film according to claim 1,
wherein the liquid crystal polymer has a constitutional unit represented by any of Formulae (1) to (3),
—O—Ar¹—CO— Formula (1)
—CO—Ar²—CO— Formula (2)
—X—Ar³—Y— Formula (3)
in Formulae (1) to (3), Ar¹ represents a phenylene group, a naphthylene group, or a biphenylylene group, Are and Ar³ each independently represent a phenylene group, a naphthylene group, a biphenylylene group, or a group represented by Formula (4), X and Y each independently represent an oxygen atom or an imino group, and hydrogen atoms in Ar¹ to Ar³ may be each independently substituted with a halogen atom, an alkyl group, or an aryl group,
—Ar⁴—Z—Ar⁵— Formula (4)
in Formula (4), Ar⁴ and Ar⁵ each independently represent a phenylene group or a naphthylene group, and Z represents an oxygen atom, a sulfur atom, a carbonyl group, a sulfonyl group, or an alkylene group.

13. A laminate comprising:
the liquid crystal polymer film according to claim 1; and
a metal layer disposed on at least one surface of the liquid crystal polymer film.

14. A laminate comprising:
the liquid crystal polymer film according to claim 6; and
a metal layer disposed on a surface of the layer B side.

15. The laminate according to claim 14,
wherein a thickness of the layer B is larger than a thickness of the metal layer.

16. The laminate according to claim 14,
wherein the metal layer is a copper layer, and
a peel strength between the layer B and the copper layer is 0.5 kN/m or more.

17. A laminate comprising:
the liquid crystal polymer film according to claim 7; and
a metal layer disposed on a surface of the layer C side.

18. The laminate according to claim 17,
wherein the metal layer is a copper layer, and
a peel strength between the layer C and the copper layer is 0.5 kN/m or more.

19. A method for manufacturing the liquid crystal polymer film according to claim 1, the method comprising, in the following order:
a casting step of extruding a composition containing the liquid crystal polymer and a solvent A onto a support to produce a casting film;
a liquid immersion step of immersing the casting film in a solvent B having a boiling point lower than a melting point of the liquid crystal polymer; and
a drying step of removing at least a part of the solvent B contained in the casting film.
